(19) United States
(12) Patent Application Publication
(10) Pub. No.: US 2025/0220923 A1
(43) Pub. Date: Jul. 3, 2025

(54) MEMORY CIRCUIT, RESISTIVE NON-VOLATILE MEMORY AND OPERATION METHOD THEREOF

(71) Applicant: eRaytroniks Co., Ltd., Kaohsiung City (TW)

(72) Inventors: E Ray HSIEH, Taoyuan City (TW); Yuan Heng TSENG, Tainan City (TW)

(21) Appl. No.: 18/974,692

(22) Filed: Dec. 9, 2024

Related U.S. Application Data
(60) Provisional application No. 63/615,268, filed on Dec. 27, 2023.

(30) Foreign Application Priority Data
Aug. 5, 2024 (TW) 113129137

(51) Int. Cl. H10B 63/00; G11C 13/00; H10N 70/20

(52) U.S. Cl. CPC H10B 63/20; G11C 13/003; G11C 13/004; G11C 13/0069; H10B 63/80; H10N 70/253; G11C 2013/0083; G11C 2213/53; G11C 2213/72

(57) ABSTRACT

The present disclosure provides a resistive non-volatile memory, which includes at least one gate-resistively-changeable field effect transistor and a unipolar source/channel/drain diode. least The at one gate-resistively-changeable field effect transistor is electrically connected to at least one bit line. The unipolar source/channel/drain diode is implemented by a field effect transistor without the gate electrode. Two terminals of the unipolar source/channel/drain diode are electrically connected to a source line and the at least one gate-resistively-changeable field effect transistor.

### RELATED APPLICATIONS

This application claims priority to U.S. Provisional Patent Application No. 63/615,268, filed Dec. 27, 2023 and Taiwan Patent Application No. 113129137, filed Aug. 5, 2024, the entirety of which is herein incorporated by reference.

### BACKGROUND

### Field of Invention

The present invention relates to storage circuits and operation methods, and more particularly, a memory circuit, a resistive non-volatile memory and an operating method thereof.

### Description of Related Art

With the progress of Moore's Law, various embedded memories have been mass-produced in foundries. In many application fields, semiconductor memory is widely used in various electronic products.

The traditional embedded memories have been formed in the front-end-of-line (FEOL) and back-end-of-line (BEOL) of the CMOS technology separately, which increases numbers of lithographic masks and manufacturing steps, resulting in cost deficiency. In addition, traditional embedded memory technologies use the three-terminal active devices as the control transistors, which need additional word-lines and relative peripheral circuits, leading to increase of the power consumption and the chip layout-overhead.

### SUMMARY

In one or more various aspects, the present disclosure is directed to a memory circuit, a resistive non-volatile memory and an operating method thereof.

One embodiment of the present disclosure is related to a resistive non-volatile memory. The resistive non-volatile memory includes at least one gate-resistively-changeable field effect transistor and a unipolar source/channel/drain diode. The at least one gate-resistively-changeable field effect transistor is electrically connected to at least one bit line. The unipolar source/channel/drain diode is implemented by a field effect transistor without a gate electrode, and two terminals of the unipolar source/channel/drain diode are electrically connected to a source line and the at least one gate-resistively-changeable field effect transistor respectively.

In one embodiment of the present disclosure, a gate of the at least one gate-resistively-changeable field effect transistor is electrically connected to the at least one bit line, and a first terminal of the at least one gate-resistively-changeable field effect transistor is floated, two terminals of the unipolar source/channel/drain diode are electrically connected to the source line and a second terminal of the at least one gate-resistively-changeable field effect transistor, and the unipolar source/channel/drain diode is a npn diode or a nin diode.

In one embodiment of the present disclosure, the unipolar source/channel/drain diode includes a floating dummy gate, a first source/drain diffusion region and a second source/drain diffusion region. The first source/drain diffusion region and the second source/drain diffusion region are disposed at opposite sides of the floating dummy gate, where the first source/drain diffusion region contacts a terminal of a contact plug, and another terminal of the contact plug contacts the source line.

In one embodiment of the present disclosure, the unipolar source/channel/drain diode and the at least one gate-resistively-changeable field effect transistor share the second source/drain diffusion region, and the at least one gate-resistively-changeable field effect transistor includes a shallow trench isolation. The shallow trench isolation is in direct contact with the gate of the at least one gate-resistively-changeable field effect transistor, where the shallow trench isolation and the second source/drain diffusion region are respectively disposed at opposite sides of the gate of the at least one gate-resistively-changeable field effect transistor, the shallow trench isolation serves as the first terminal of the at least one gate-resistively-changeable field effect transistor, and the second source/drain diffusion region serves as the second terminal of the at least one gate-resistively-changeable field effect transistor.

In one embodiment of the present disclosure, two terminals of the unipolar source/channel/drain diode are electrically connected to the source line and a gate of the at least one gate-resistively-changeable field effect transistor respectively, a first terminal of the at least one gate-resistively-changeable field effect transistor is floated, a second terminal of the at least one gate-resistively-changeable field effect transistor is electrically connected to the at least one bit line, and the unipolar source/channel/drain diode is a pnp diode or a pip diode.

In one embodiment of the present disclosure, the unipolar source/channel/drain diode includes a floating dummy gate, a first source/drain diffusion region and a second source/drain diffusion region. The first source/drain diffusion region and the second source/drain diffusion region are disposed at opposite sides of the floating dummy gate.

In one embodiment of the present disclosure, resistive non-volatile memory, further includes a first conductive layer, a second conductive layer, a first contact plug, a second contact plug, a third contact plug and a fourth contact plug. The first conductive layer and the second conductive layer are electrically isolated from each other. The first contact plug has two terminals in contact with the first source/drain diffusion region and the first conductive layer respectively. The second contact plug has two terminals in contact with the first conductive layer and the source line respectively. The third contact plug has two terminals in contact with the second source/drain diffusion region and the second conductive layer respectively. The fourth contact plug has two terminals in contact with the gate of the at least one gate-resistively-changeable field effect transistor and the second conductive layer respectively.

In one embodiment of the present disclosure, the at least one gate-resistively-changeable field effect transistor includes a shallow trench isolation and a third source/drain diffusion region. The shallow trench isolation is in direct contact with the gate of the at least one gate-resistively-changeable field effect transistor, and the shallow trench isolation serves as the first terminal of the at least one gate-resistively-changeable field effect transistor. The third source/drain diffusion region and the shallow trench isolation are disposed at opposite sides of the gate of the at least one gate-resistively-changeable field effect transistor, and the third source/drain diffusion region serves as the second terminal of the at least one gate-resistively-changeable field effect transistor.

In one embodiment of the present disclosure, the resistive non-volatile memory further includes a fifth contact plug having two terminals contact the third source/drain diffusion region and the at least one bit line respectively.

Another embodiment of the present disclosure is related to a memory circuit, which includes a plurality of memory units arranged in an array, each of the memory units includes a resistive non-volatile memory, and the resistive non-volatile memory includes at least one gate-resistively-changeable field effect transistor and a unipolar source/channel/drain diode. The at least one gate-resistively-changeable field effect transistor is electrically connected to at least one bit line. The unipolar source/channel/drain diode is implemented by a field effect transistor without a gate electrode, two terminals of the unipolar source/channel/drain diode are respectively electrically connected to a source line and the at least one gate-resistively-changeable field effect transistor.

In one embodiment of the present disclosure, each of the memory units includes another resistive non-volatile memory, and a terminal of the another resistive non-volatile memory is electrically connected to the resistive non-volatile memory and the at least one bit line, and another terminal of the another resistive non-volatile memory is electrically connected to another source line.

In one embodiment of the present disclosure, each of the memory units includes another resistive non-volatile memory, and a terminal of the another resistive non-volatile memory is electrically connected to the resistive non-volatile memory and the source line, and another terminal of the another resistive non-volatile memory is electrically connected to the at least one bit line.

In one embodiment of the present disclosure, a gate of the at least one gate-resistively-changeable field effect transistor is electrically connected to the at least one bit line, a first terminal of the at least one gate-resistively-changeable field effect transistor is floated, two terminals of the unipolar source/channel/drain diode are electrically connected to the source line and a second terminal of the at least one gate-resistively-changeable field effect transistor, each of the memory units includes another resistive non-volatile. memory, and the another resistive non-volatile memory includes at least another gate-resistively-changeable field effect transistor and another unipolar source/channel/drain diode. The at least another gate-resistively-changeable field effect transistor has a gate electrically connected to at least another bit line, and a first terminal of the at least another gate-resistively-changeable field effect transistor is floated. The another unipolar source/channel/drain diode is implemented by another field effect transistor without a gate electrode, two terminals of the another unipolar source/channel/drain diode are respectively electrically connected to the source line and a second terminal of the at least another gate-resistively-changeable field effect transistor.

In one embodiment of the present disclosure, two terminals of the unipolar source/channel/drain diode are electrically connected to the source line and a gate of the at least one gate-resistively-changeable field effect transistor, a first terminal of the at least one gate-resistively-changeable field effect transistor is floated, a second terminal of the at least one gate-resistively-changeable field effect transistor is electrically connected to the at least one bit line, each of the memory units includes another resistive non-volatile memory, and the another resistive non-volatile includes another memory at least gate-resistively-changeable field effect transistor and another unipolar source/channel/drain diode. The at least another gate-resistively-changeable field effect transistor has a first terminal being floated, and a second terminal of the at least another gate-resistively-changeable field effect transistor is electrically connected to the at least one bit line. The another unipolar source/channel/drain diode is implemented by another field effect transistor without a gate electrode, two terminals of the another unipolar source/channel/drain diode are electrically connected to another source line and a gate of the at least another gate-resistively-changeable field effect transistor.

Another embodiment of the present disclosure is related to an operation method of a resistive non-volatile memory, the resistive non-volatile memory includes a gate-resistively-changeable field effect transistor and a unipolar source/channel/drain diode connected to each other, and the operation method includes steps of: applying a zero voltage to one of a bit line and a source line, and applying a nonzero voltage to another of the bit line and the source line to operate the resistive non-volatile memory, wherein the gate-resistively-changeable field effect transistor is electrically connected to the bit line, the unipolar source/channel/drain diode is implemented by a field effect transistor without a gate electrode, two terminals of the unipolar source/channel/drain diode are electrically connected to the source line and the gate-resistively-changeable field effect transistor respectively.

In one embodiment of the present disclosure, a gate of the gate-resistively-changeable field effect transistor is electrically connected to the bit line, a first terminal of the gate-resistively-changeable field effect transistor is floated, two terminals of the unipolar source/channel/drain diode are electrically connected to the source line and a second terminal of the gate-resistively-changeable field effect transistor, the unipolar source/channel/drain diode is a npn diode or a nin diode, and the operation methods includes: in a forming process, when the resistive non-volatile memory is selected, applying a forming voltage to the bit line, and applying the zero voltage to the source line; in a setting process, when the resistive non-volatile memory is selected, applying a setting voltage to the bit line, and applying the zero voltage to the source line, wherein an absolute value of the setting voltage is less than or equal to an absolute value of the forming voltage; in a resetting process, when the resistive non-volatile memory is selected, applying a resetting voltage to the bit line, and applying the zero voltage to the source line, wherein an absolute value of the resetting voltage is less than the absolute value of the setting voltage; and in a reading process, when the resistive non-volatile memory is selected, applying a reading voltage to the bit line, and applying the zero voltage to the source line, where an absolute value of the reading voltage is less than the absolute value of the resetting voltage.

In one embodiment of the present disclosure, the operation method further includes: in the forming process, when the resistive non-volatile memory is not selected, applying a voltage between one-half and one-fifth of the forming voltage to the source line, and applying the zero voltage is applied to the bit line; in the setting process, when the resistive non-volatile memory is not selected, applying a voltage between one-half and one-fifth of the setting voltage to the source line, and applying the zero voltage to the bit line; in the resetting process, when the resistive non-volatile memory is not selected, applying a voltage between one-half and one-fifth of the resetting voltage to the source line, and applying the zero voltage to the bit line; and in the reading process, when the resistive non-volatile memory is not selected, applying a voltage between one-half and one-fifth of the reading voltage to the source line, and applying the zero voltage to the bit line.

In one embodiment of the present disclosure, two terminals of the unipolar source/channel/drain diode are electrically connected to the source line and a gate of the gate-resistively-changeable field effect transistor, a first terminal of the gate-resistively-changeable field effect transistor is floated, a second terminal of the gate-resistively-changeable field effect transistor is electrically connected to the bit line, the unipolar source/channel/drain diode is a pnp diode or a pip diode, and the operation methods includes: in a forming process, when the resistive non-volatile memory is selected, applying a forming voltage to the source line, and applying the zero voltage to the bit line; in a setting process, when the resistive non-volatile memory is selected, applying a setting voltage to the source line, and applying the zero voltage to the bit line, wherein an absolute value of the setting voltage is less than or equal to an absolute value of the forming voltage; in a resetting process, when the resistive non-volatile memory is selected, applying a resetting voltage to the source line, and applying the zero voltage to the bit line, wherein an absolute value of the resetting voltage is less than the absolute value of the setting voltage; and in a reading process, when the resistive non-volatile memory is selected, applying a reading voltage to the source line, and applying the zero voltage to the bit line, wherein an absolute value of the reading voltage is less than the absolute value of the resetting voltage.

In one embodiment of the present disclosure, the operation method further includes: in the forming process, when the resistive non-volatile memory is not selected, applying a voltage between one-half and one-fifth of the forming voltage to the bit line, and applying the zero voltage to the source line; in the setting process, when the resistive non-volatile memory is not selected, applying a voltage between one-half and one-fifth of the setting voltage to the bit line, and applying the zero voltage to the source line; in the resetting process, when the resistive non-volatile memory is not selected, applying a voltage between one-half and one-fifth of the resetting voltage to the bit line, and applying the zero voltage to the source line; and in the reading process, when the resistive non-volatile memory is not selected, applying a voltage between one-half and one-fifth of the reading voltage to the bit line, and applying the zero voltage to the source line.

Technical advantages are generally achieved, by embodiments of the present disclosure. The resistive non-volatile memory of the present disclosure does not require additional word lines and related circuits, achieving the ultra-scaled chip size in favor of CMOS continual scaling and simpler configuration arrangement of the chip with higher cost efficiency.

Many of the attendant features will be more readily appreciated, as the same becomes better understood by reference to the following detailed description considered in connection with the accompanying drawings.

### BRIEF DESCRIPTION OF THE DRAWINGS

The invention can be more fully understood by reading the following detailed description of the embodiment, with reference made to the accompanying drawings as follows:

FIG. 1A is a circuit diagram of a unipolar source/channel/drain diode according to some embodiments of the present disclosure;

FIG. 1B is a circuit diagram of a unipolar source/channel/drain diode according to some embodiments of the present disclosure;

FIG. 1C is a circuit diagram of a unipolar source/channel/drain diode according to some embodiments of the present disclosure;

FIG. 1D is a circuit diagram of a unipolar source/channel/drain diode according to some embodiments of the present disclosure;

FIG. 2 illustrates the electrical characteristic of the unipolar source/channel/drain diode of FIG. 1D;

FIG. 3A is a circuit diagram of a resistive non-volatile memory according to some embodiments of the present disclosure;

FIG. 3B is a circuit diagram of a resistive non-volatile memory according to some embodiments of the present disclosure;

FIG. 3C is a circuit diagram of a resistive non-volatile memory according to some embodiments of the present disclosure;

FIG. 3D is a circuit diagram of a resistive non-volatile memory according to some embodiments of the present disclosure;

FIG. 4A is a circuit diagram of a resistive non-volatile memory according to some embodiments of the present disclosure;

FIG. 4B is a circuit diagram of a resistive non-volatile memory according to some embodiments of the present disclosure;

FIG. 4C is a circuit diagram of a resistive non-volatile memory according to some embodiments of the present disclosure;

FIG. 4D is a circuit diagram of a resistive non-volatile memory according to some embodiments of the present disclosure;

FIG. 5A is a circuit diagram of a memory circuit according to some embodiments of the present disclosure;

FIG. 5B is a circuit diagram of a memory circuit according to some embodiments of the present disclosure;

FIG. 5C is a circuit diagram of a memory circuit according to some embodiments of the present disclosure;

FIG. 6A is a circuit diagram of a memory unit according to some embodiments of the present disclosure;

FIG. 6B is a circuit diagram of a memory unit according to some embodiments of the present disclosure;

FIG. 6C is a circuit diagram of a memory unit according to some embodiments of the present disclosure;

FIG. 7A is a circuit diagram of a resistive non-volatile memory according to some embodiments of the present disclosure;

FIG. 7B is a schematic layout diagram of a resistive non-volatile memory according to some embodiments of the present disclosure;

FIG. 7C is a cross-sectional view of a resistive non-volatile memory according to some embodiments of the present disclosure;

FIG. 8A is a circuit diagram of a memory unit according to some embodiments of the present disclosure;

FIG. 8B is a schematic layout diagram of a memory unit according to some embodiments of the present disclosure;

FIG. 8C is a cross-sectional view of a memory unit according to some embodiments of the present disclosure;

FIG. 9A is a circuit diagram of a resistive non-volatile memory according to some embodiments of the present disclosure;

FIG. 9B is a circuit diagram of a resistive non-volatile memory according to some embodiments of the present disclosure;

FIG. 10A is a circuit diagram of a resistive non-volatile memory according to some embodiments of the present disclosure;

FIG. 10B is a circuit diagram of a resistive non-volatile memory according to some embodiments of the present disclosure;

FIG. 10C is a circuit diagram of a resistive non-volatile memory according to some embodiments of the present disclosure;

FIG. 10D is a circuit diagram of a resistive non-volatile memory according to some embodiments of the present disclosure;

FIG. 11 is a circuit diagram of a memory circuit according to some embodiments of the present disclosure;

FIG. 12A is a circuit diagram of a resistive non-volatile memory according to some embodiments of the present disclosure;

FIG. 12B is a schematic layout diagram of a resistive non-volatile memory according to some embodiments of the present disclosure;

FIG. 12C is a cross-sectional view of a resistive non-volatile memory according to some embodiments of the present disclosure;

FIG. 13A is a circuit diagram of a resistive non-volatile memory according to some embodiments of the present disclosure;

FIG. 13B is a schematic layout diagram of a resistive non-volatile memory according to some embodiments of the present disclosure; and

FIG. 13C is a cross-sectional view of a resistive non-volatile memory according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

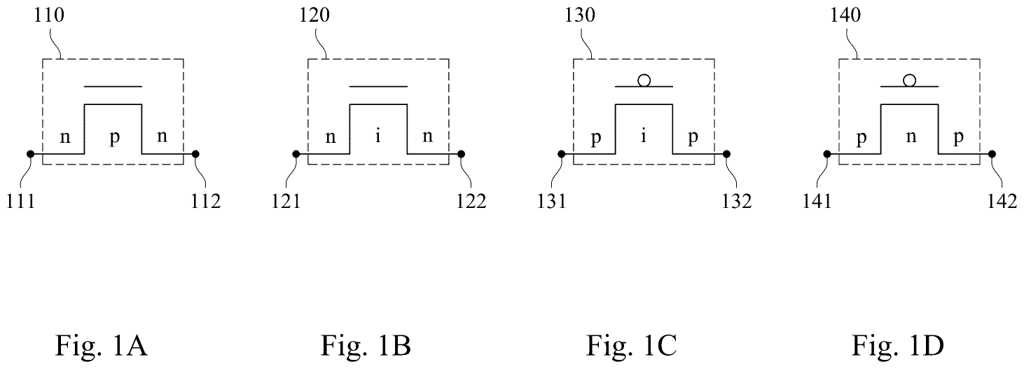

FIG. 1A is a circuit diagram of a unipolar source/channel/drain diode 110 according to some embodiments of the present disclosure. As shown in FIG. 1A, the unipolar source/channel/drain diode 110 is an npn diode. The unipolar source/channel/drain diode 110 is implemented by a field effect transistor without a gate electrode to be compatible with the semiconductor manufacturing process. For example, the two terminals 111 and 112 of the unipolar source/channel/drain diode 110 are the source and the drain respectively.

FIG. 1B is a circuit diagram of a unipolar source/channel/drain diode 120 according to some embodiments of the present disclosure. As shown in FIG. 1B, the unipolar source/channel/drain diode 120 is a nin diode. The unipolar source/channel/drain diode 120 is implemented by a field effect transistor without a gate electrode to be compatible with the semiconductor manufacturing process. For example, the two terminals 121 and 122 of the unipolar source/channel/drain diode 120 are the source and the drain respectively.

FIG. 1C is a circuit diagram of a unipolar source/channel/drain diode 130 according to some embodiments of the present disclosure. As shown in FIG. 1C, the unipolar source/channel/drain diode 130 is a pip diode. The unipolar source/channel/drain diode 130 is implemented by a field effect transistor without a gate electrode to be compatible with the semiconductor manufacturing process. For example, the two terminals 131 and 132 of the unipolar source/channel/drain diode 130 are the source and the drain respectively.

FIG. 1D is a circuit diagram of a unipolar source/channel/drain diode 140 according to some embodiments of the present disclosure. As shown in FIG. 1D, the unipolar source/channel/drain diode 140 is a pnp diode. The unipolar source/channel/drain diode 140 is implemented by a field effect transistor without a gate electrode to be compatible with the semiconductor manufacturing process. For example, the two terminals 141 and 142 of the unipolar source/channel/drain diode 140 are the source and the drain respectively.

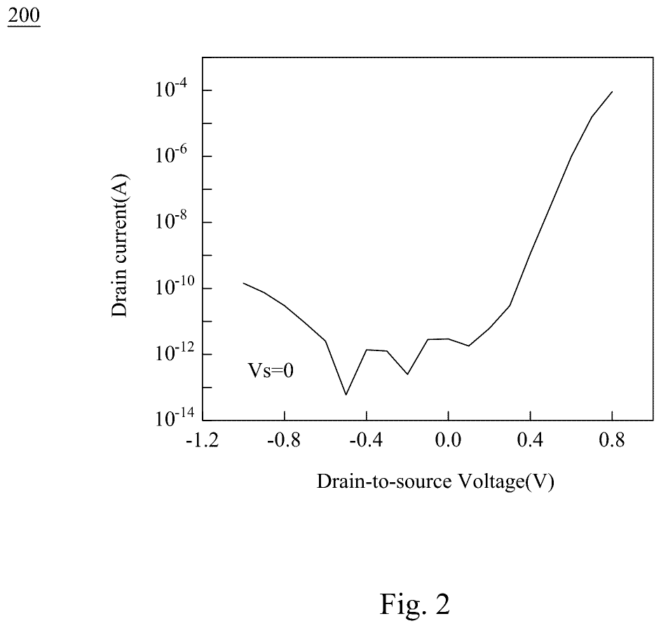

FIG. 2 illustrates the electrical characteristic 200 of the unipolar source/channel/drain diode 140 of FIG. 1D. As shown in FIG. 2, the unipolar source/channel/drain diode 140 has unipolar rectification characteristics. When the drain-to-source voltage of the unipolar source/channel/drain diode 140 is greater than the zero voltage, the drain current is forwardly conducted; when the drain-to-source voltage of the unipolar source/channel/drain diode 140 is less than the zero voltage, the drain current is reversed saturated.

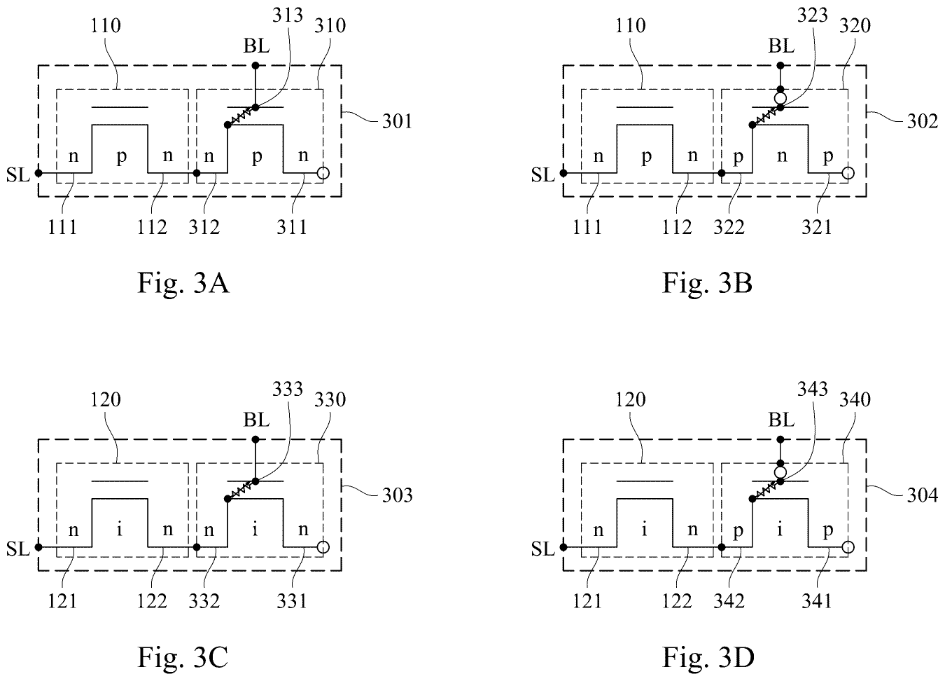

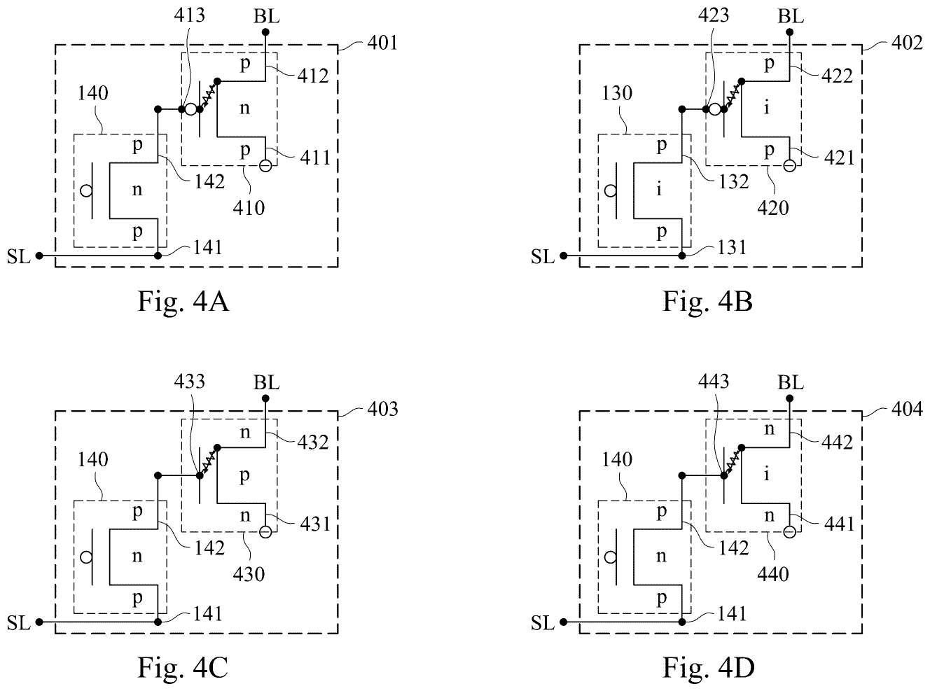

Referring to FIGS. 3A-3D and 4A-4D, in one aspect, the present disclosure is directed to the resistive non-volatile memories 301-304 and 401-404. The resistive non-volatile memories 301-304 and 401-404 may be easily applied in embedded resistive non-volatile memories and may be applicable or readily adaptable to all technologies. Technical advantages are generally achieved by the resistive non-volatile memories 301-304 and 401-404 according to embodiments of the present disclosure. Herewith the resistive non-volatile memories 301-304 and 401-404 are described below with FIGS. 3A-3D and 4A-4D.

The subject disclosure provides the resistive non-volatile memories 301-304 and 401-404 in accordance with the subject technology. Various aspects of the present technology are described with reference to the drawings. In the following description, for purposes of explanation, numerous specific details are set forth in order to provide a thorough understanding of one or more aspects. It can be evident, however, that the present technology can be practiced without these specific details. In other instances, well-known structures and devices are shown in block diagram form in order to facilitate describing these aspects. The word “exemplary” is used herein to mean “serving as an example, instance, or illustration.” Any embodiment described herein as “exemplary” is not necessarily to be construed as preferred or advantageous over other embodiments.

FIG. 3A is a circuit diagram of a resistive non-volatile memory 301 according to some embodiments of the present disclosure. As shown in FIG. 3A, the resistive non-volatile memory 301 includes a gate-resistively-changeable field effect transistor 310 and a unipolar source/channel/drain diode 110. Structurally, the gate-resistively-changeable field effect transistor 310 is electrically connected to the bit line BL, and the two terminals 111 and 112 of the unipolar source/channel/drain diode 110 are electrically connected to the source line SL and the gate-resistively-changeable field effect transistor 310 respectively.

In FIG. 3A, the gate 313 of the gate-resistively-changeable field effect transistor 310 is electrically connected to the bit line BL, the first terminal 311 of the gate-resistively-changeable field effect transistor 310 is floated, and the two terminals 111 and 112 of the unipolar source/channel/drain diode 110 electrically connected to the source line SL and the second terminal 312 of the gate-resistively-changeable field effect transistor 310 respectively. The unipolar source/channel/drain diode 110 is an diode, and the npn gate-resistively-changeable field effect transistor 310 is an npn gate-resistively-changeable field effect transistor.

It should be noted that although the terms “first”, “second”, etc. may be used here to describe various components, these components should not be limited by these terms. These terms are only used to distinguish one element from another element. For example, a first element could be termed a second element, and similarly, a second element could be termed a first element, without departing from the scope of the embodiments.

FIG. 3B is a circuit diagram of a resistive non-volatile memory 302 according to one of the embodiments of the present disclosure. As shown in FIG. 3B, the resistive non-volatile memory 302 includes a gate-resistively-changeable field effect transistor 320 and a unipolar source/channel/drain diode 110. Structurally, the gate-resistively-changeable field effect transistor 320 is electrically connected to the bit line BL, and the two terminals 111 and 112 of the unipolar source/channel/drain diode 110 are electrically connected to the source line SL and the gate-resistively-changeable field effect transistor 320 respectively.

In FIG. 3B, the gate 323 of the gate-resistively-changeable field effect transistor 320 is electrically connected to the bit line BL, the first terminal 321 of the gate-resistively-changeable field effect transistor 320 is floated, and the two terminals 111 and 112 of the unipolar source/channel/drain diode 110 are electrically connected to the source line SL and the second terminal 322 of the gate-resistively-changeable field effect transistor 320 respectively. The unipolar source/channel/drain diode 110 is an and the npn diode, gate-resistively-changeable field effect transistor 320 is a pnp gate-resistively-changeable field effect transistor.

FIG. 3C is a circuit diagram of a resistive non-volatile memory 303 according to some embodiments of the present disclosure. As shown in FIG. 3C, the resistive non-volatile memory 303 includes the gate-resistively-changeable field effect transistor 330 and the unipolar source/channel/drain diode 120. Structurally, the gate-resistively-changeable field effect transistor 330 is electrically connected to the bit line BL, and the two terminals 121 and 122 of the unipolar source/channel/drain diode 120 are electrically connected to the source line SL and the gate-resistively-changeable field effect transistor 330 respectively.

In FIG. 3C, the gate 333 of the gate-resistively-changeable field effect transistor 330 is electrically connected to the bit line BL, the first terminal 331 of the gate-resistively-changeable field effect transistor 330 is floated, and the two terminals 121 and 122 of the unipolar source/channel/drain diode 120 are electrically connected to the source line SL and the second terminal 332 of the gate-resistively-changeable field effect transistor 330 respectively. The unipolar source/channel/drain diode 120 is a nin diode, and the gate-resistively-changeable field effect transistor 330 is a nin resistive-changeable field effect transistor.

FIG. 3D is a circuit diagram of a resistive non-volatile memory 304 according to some embodiments of the present disclosure. As shown in FIG. 3D, the resistive non-volatile memory 304 includes the gate-resistively-changeable field effect transistor 340 and the unipolar source/channel/drain diode 120. Structurally, the gate-resistively-changeable field effect transistor 340 is electrically connected to the bit line BL, and the two terminals 121 and 122 of the unipolar source/channel/drain diode 120 are electrically connected to the source line SL and the gate-resistively-changeable field effect transistor 340 respectively.

In FIG. 3D, the gate 343 of the gate-resistively-changeable field effect transistor 340 is electrically connected to the bit line BL, the first terminal 341 of the gate-resistively-changeable field effect transistor 340 is floated, and the two terminals 121 and 122 of the unipolar source/channel/drain diode 120 are electrically connected to the source line SL and the second terminal 342 of the gate-resistively-changeable field effect transistor 340 respectively. The unipolar source/channel/drain diode 120 is a nin diode, and the gate-resistively-changeable field effect transistor 330 is a pip gate-resistively-changeable field effect transistor.

In some embodiments of the present disclosure, the operating methods of resistive non-volatile memories 301-304 are all the same. In order to simplify the explanation, the following takes the operation of resistive non-volatile memory 301 as an example, a zero voltage is applied to one of the bit line BL and source line SL, and a nonzero voltage is applied to the other of bit line BL and source line SL, so as to operate the resistive non-volatile memory 301.

Specifically, in the forming process, when the resistive non-volatile memory 301 is selected, the forming voltage is applied to the bit line BL, and the zero voltage is applied to the source line SL, so that the gate dielectric layer of the gate of the gate-resistively-changeable field effect transistor 310 can form a conductive filament; in the setting process, when resistive non-volatile memory 301 is selected, a setting voltage is applied to the bit line BL, and a zero voltage is applied to the source line SL, so that the gate dielectric layer of the gate of the gate-resistively-changeable field effect transistor 310 can be in the first resistance state, where the absolute value of the setting voltage is less than or equal to the absolute value of the forming voltage; in the resetting process, when resistive non-volatile memory 301 is selected, the resetting voltage is applied to the bit line BL, and the zero voltage is applied to the source line SL, so that the gate dielectric layer of the gate of the gate-resistively-changeable field effect transistor 310 can be in the second resistance state, where the absolute value of the resetting voltage is less than the absolute value of the setting voltage; in the reading process, when resistive non-volatile memory 301 is selected, the reading voltage is applied to bit line BL, and the zero voltage is applied to source line SL, where the absolute value of the reading voltage is less than the absolute value of resetting voltage. The reading circuit is based on the level of the read current to determine whether the resistive non-volatile memory 301 has been set or reset.

On the other hand, in the forming process, when the resistive non-volatile memory 301 is not selected, a voltage between one-half and one-fifth of the forming voltage is applied to the source line SL, and the zero voltage is applied to the bit line BL; in the setting process, when resistive non-volatile memory 301 is not selected, a voltage between one-half and one-fifth of the setting voltage is applied to the source line SL, and the zero voltage is applied to the bit line BL; in the resetting process, when the resistive non-volatile memory 301 is not selected, a voltage between one-half and one-fifth of the resetting voltage is applied to the source line SL, and the zero voltage is applied to the bit line BL; in the reading process, when the resistive non-volatile memory 301 is not selected, a voltage between one-half and one-fifth of the reading voltage is applied to the source line SL, and the zero voltage is applied to the bit line BL.

FIG. 4A is a circuit diagram of a resistive non-volatile memory 401 according to some embodiments of the present disclosure. As shown in FIG. 4A, the resistive non-volatile memory 401 includes a gate-resistively-changeable field effect transistor 410 and a unipolar source/channel/drain diode 140. Structurally, the gate-resistively-changeable field effect transistor 410 is electrically connected to the bit line BL, and the two terminals 141 and 142 of the unipolar source/channel/drain diode 140 are electrically connected to the source line SL and the gate-resistively-changeable field effect transistor 410 respectively.

In FIG. 4A, the two terminals 141 and 142 of the unipolar source/channel/drain diode 140 are electrically connected to the source line SL and the gate 413 of the gate-resistively-changeable field effect transistor 410 respectively, the first terminal 411 of the gate-resistively-changeable field effect transistor 410 is floated, and the second terminal 412 of the gate-resistively-changeable field effect transistor 410 is electrically connected to the bit line BL. The unipolar source/channel/drain diode 140 is a pnp diode, and the gate-resistively-changeable field effect transistor 410 is a pnp gate-resistively-changeable field effect transistor.

FIG. 4B is a circuit diagram of a resistive non-volatile memory 402 according to some embodiments of the present disclosure. As shown in FIG. 4B, the resistive non-volatile memory 402 includes a gate-resistively-changeable field effect transistor 420 and a unipolar source/channel/drain diode 130. Structurally, the gate-resistively-changeable field effect transistor 420 is electrically connected to the bit line BL, and the two terminals 131 and 132 of the unipolar source/channel/drain diode 130 are electrically connected to the source line SL and the gate-resistively-changeable field effect transistor 420 respectively.

In FIG. 4B, the two terminals 131 and 132 of the unipolar source/channel/drain diode 130 are electrically connected to the source line SL and the gate 423 of the gate-resistively-changeable field effect transistor 420 respectively, the first terminal 421 of the gate-resistively-changeable field effect transistor 420 is floated, and the second terminal 422 of the gate-resistively-changeable field effect transistor 420 is electrically connected to the bit line BL. The unipolar source/channel/drain diode 130 is a pip diode, and the gate-resistively-changeable field effect transistor 420 is a pip gate-resistively-changeable field effect transistor.

FIG. 4C is a circuit diagram of a resistive non-volatile memory 403 according to some embodiments of the present disclosure. As shown in FIG. 4C, the resistive non-volatile memory 403 includes the gate-resistively-changeable field effect transistor 430 and the unipolar source/channel/drain diode 140. Structurally, the gate-resistively-changeable field effect transistor 430 is electrically connected to the bit line BL, and the two terminals 141 and 142 of the unipolar source/channel/drain diode 140 are electrically connected to the source line SL and the gate-resistively-changeable field effect transistor 430 respectively.

In FIG. 4C, the two terminals 141 and 142 of the unipolar source/channel/drain diode 140 are electrically connected to the source line SL and the gate 433 of the gate-resistively-changeable field effect transistor 430 respectively, the first terminal 431 of the gate-resistively-changeable field effect transistor 430 is floated, and the second terminal 432 of the gate-resistively-changeable field effect transistor 430 is electrically connected to the bit line BL. The unipolar source/channel/drain diode 140 is a pnp diode, and the gate-resistively-changeable field effect transistor 430 is an npn gate-resistively-changeable field effect transistor.

FIG. 4D is a circuit diagram of a resistive non-volatile memory 404 according to some embodiments of the present disclosure. As shown in FIG. 4D, the resistive non-volatile memory 404 includes a gate-resistively-changeable field effect transistor 440 and a unipolar source/channel/drain diode 140. Structurally, the gate-resistively-changeable field effect transistor 440 is electrically connected to the bit line BL, and the two terminals 141 and 142 of the unipolar source/channel/drain diode 140 are electrically connected to the source line SL and the gate-resistively-changeable field effect transistor 440 respectively.

In FIG. 4D, the two terminals 141 and 142 of the unipolar source/channel/drain diode 140 are electrically connected to the source line SL and the gate 443 of the gate-resistively-changeable field effect transistor 440 respectively, the first terminal 441 of the gate-resistively-changeable field effect transistor 440 is floated, and the second terminal 442 of the gate-resistively-changeable field effect transistor 440 is electrically connected to the bit line BL. The unipolar source/channel/drain diode 140 is a pnp diode, and the gate-resistively-changeable field effect transistor 440 is a nin gate-resistively-changeable field effect transistor.

In some embodiments of the present disclosure, the operating methods of resistive non-volatile memories 401-404 are all the same. In order to simplify the explanation, the following takes the operation of resistive non-volatile memory 403 as an example, a zero voltage is applied to one of the bit line BL and source line SL, and a nonzero voltage is applied to the other of bit line BL and source line SL, so as to operate the resistive non-volatile memory 403.

Specifically, in the forming process, when resistive non-volatile memory 403 is selected, the forming voltage is applied to the source line SL, and the zero voltage is applied to the bit line BL, so that the gate dielectric layer of the gate of the gate-resistively-changeable field effect transistor 430 can form a conductive filament; in the setting process, when resistive non-volatile memory 403 is selected, the setting voltage is applied to the source line SL, and the zero voltage is applied to the bit line BL, so that the gate dielectric layer of the gate of the gate-resistively-changeable field effect transistor 430 can be in the first resistance state, where the absolute value of the setting voltage is less than or equal to the absolute value of the forming voltage; in the resetting process, when resistive non-volatile memory 403 is selected, the resetting voltage is applied to the source line SL, and the zero voltage is applied to the bit line BL, so that the gate dielectric layer of the gate of the gate-resistively-changeable field effect transistor 430 can be in the second resistance state, where the absolute value of the resetting voltage is less than the absolute value of the setting voltage; in the reading process, when resistive non-volatile memory 403 is selected, the reading voltage is applied to the source line SL, and the zero voltage is applied to the bit line BL, where the absolute value of the reading voltage is less than the absolute value of the resetting voltage. The reading circuit is based on the level of the read current to determine whether the resistive non-volatile memory 403 has been set or reset.

On the other hand, in the forming process, when the resistive non-volatile memory 403 is not selected, a voltage between one-half and one-fifth of the forming voltage is applied to the bit line BL, and the zero voltage is applied to the source line SL; in the setting process, when resistive non-volatile memory 403 is not selected, a voltage between one-half and one-fifth of the setting voltage is applied to bit line BL, and the zero voltage is applied to the source line SL; in the resetting process, when the resistive non-volatile memory 403 is not selected, a voltage between one-half and one-fifth of the resetting voltage is applied to the bit line BL, and a zero voltage is applied to the source line SL; In the reading process, when resistive non-volatile memory 403 is not selected, a voltage between one-half and one-fifth of the reading voltage is applied to bit line BL, and zero voltage is applied to source line SL.

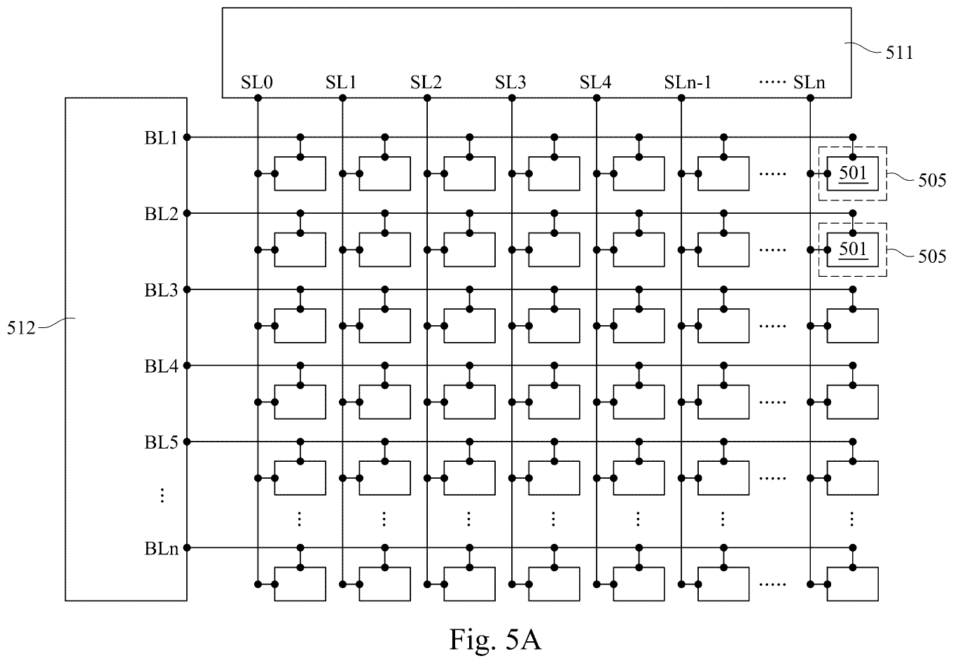

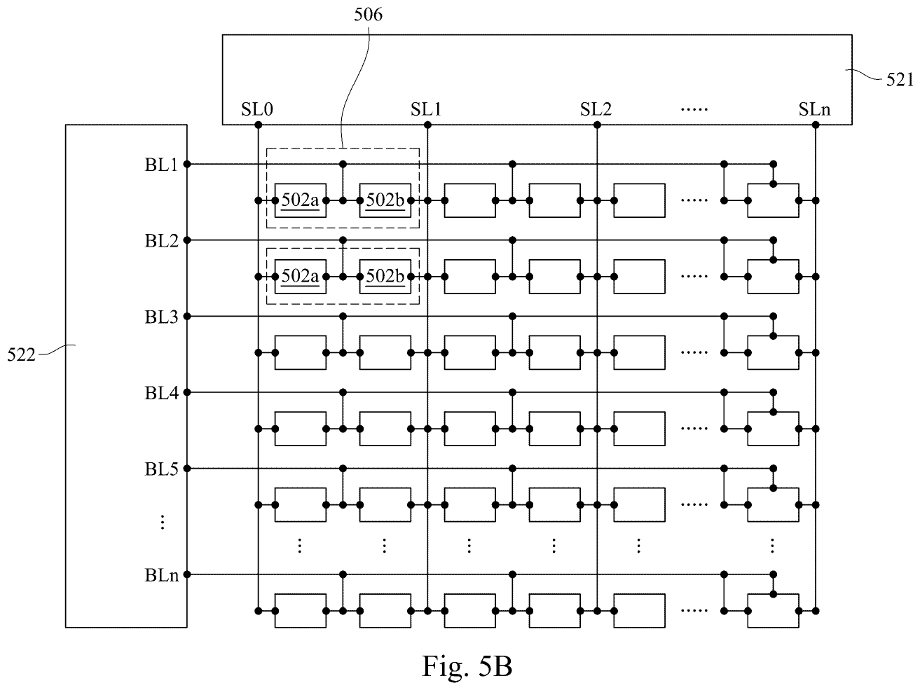

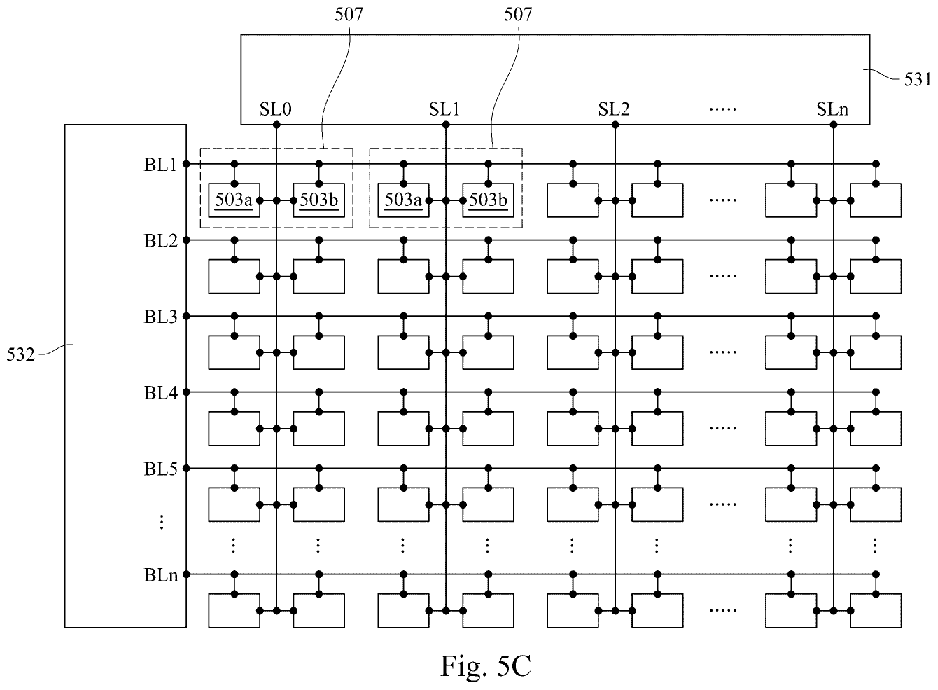

FIG. 5A is a circuit diagram of a memory circuit according to some embodiments of the present disclosure. As shown in FIG. 5A, the memory circuit includes a plurality of memory units 505 arranged in an array. Each memory unit 505 includes a resistive non-volatile memory 501. In practice, for example, the structure of the resistive non-volatile memory 501 can be any one of the above-mentioned resistive non-volatile memories 301-304 and 401-404.

In FIG. 5A, the circuit 511 is electrically connected to a terminal of the corresponding unipolar source/channel/drain diode of the resistive non-volatile memory 501 through a corresponding one of the source lines SL0-SLn, and the circuit 512 is electrically connected to a gate-resistively-changeable field effect transistor of the corresponding resistive non-volatile memory 501 through the corresponding one of the bit line BL1-BLn. In practice, for example, the circuit 511 includes a source line peripheral circuit and a control circuit, the circuit 512 includes a bit line peripheral circuit and a control circuit, and the read circuit can be selectively set in the circuit 511 or the circuit 512.

FIG. 5B is a circuit diagram of a memory circuit according to some embodiments of the present disclosure. As shown in FIG. 5B, the memory circuit includes a plurality of memory units 506 arranged in an array. Each memory unit 506 includes resistive non-volatile memories 502a and 502b. In practice, for example, the structure of the resistive non-volatile memory 502a can be any one of the above-mentioned resistive non-volatile memories 301-304 and 401-404; similarly, the structure of the resistive non-volatile memory 502b can be any one of the above-mentioned resistive non-volatile memories 301-304 and 401-404.

Taking the memory unit 506 in the corner as an example, the resistive non-volatile memory 502a and 502b share the same bit line BL1, and a terminal of the resistive non-volatile memory 502b is electrically connected to the bit line BL1 and a terminal of the resistive non-volatile memory 502a, another terminal of the resistive non-volatile memory 502b is electrically connected to the source line SL1, and another terminal of the resistive non-volatile memory 502a is electrically connected to the source line SL0.

In FIG. 5B, the circuit 521 is electrically connected to a terminal of the unipolar source/channel/drain diode of each of the corresponding resistive non-volatile memories 502a and 502b through a corresponding one of the source lines SL0-SLn, the circuit 522 is electrically connected to a gate-resistively-changeable field effect transistor of each of the corresponding resistive non-volatile memories 502a and 502b through a corresponding one of the bit lines BL1-BLn. In practice, for example, the circuit 521 includes a source line peripheral circuit and a control circuit, the circuit 522 includes a bit line peripheral circuit and a control circuit, and the read circuit can be selectively set in the circuit 521 or the circuit 522.

FIG. 5C is a circuit diagram of a memory circuit according to some embodiments of the present disclosure. As shown in FIG. 5C, the memory circuit includes a plurality of memory units 507 arranged in an array. Each memory unit 507 includes resistive non-volatile memories 503a and 503b. In practice, for example, the structure of the resistive non-volatile memory 503a can be any one of the above-mentioned resistive non-volatile memories 301-304 and 401-404; similarly, the structure of the resistive non-volatile memory 503b can be any one of the above-mentioned resistive non-volatile memories 301-304 and 401-404.

Taking the memory unit 507 in the corner as an example, the resistive non-volatile memories 503a and 503b share the same bit line BL1 and the same source line SL0. A terminal of the resistive non-volatile memory 503b is electrically connected to a terminal of the resistive non-volatile memory 503a and a source line SL0, another terminal of resistive non-volatile memory 503b is electrically connected to bit line BL1, and another terminal of the resistive non-volatile memory 503 is electrically connected to bit line BL1.

In FIG. 5C, the circuit 531 is electrically connected to a terminal of the unipolar source/channel/drain diode of each of the corresponding resistive non-volatile memories 503a and 503b through a corresponding one of source lines SL0-SLn, and the circuit 532 is electrically connected to a gate-resistively-changeable field effect transistor of each of the corresponding resistive non-volatile memories 503a and 503b through a corresponding one of bit lines BL1-BLn. In practice, for example, the circuit 531 includes a source line peripheral circuit and a control circuit, the circuit 532 includes a bit line peripheral circuit and a control circuit, and the read circuit can be selectively set in the circuit 531 or the circuit 532.

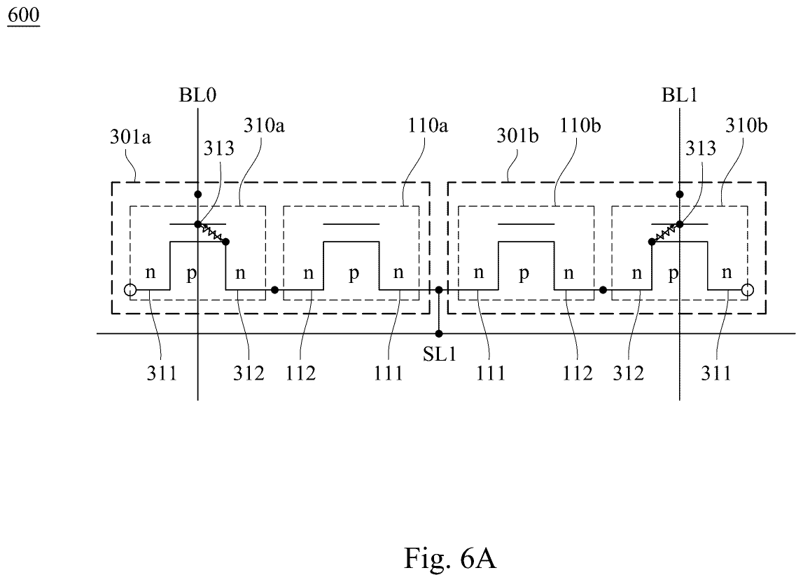

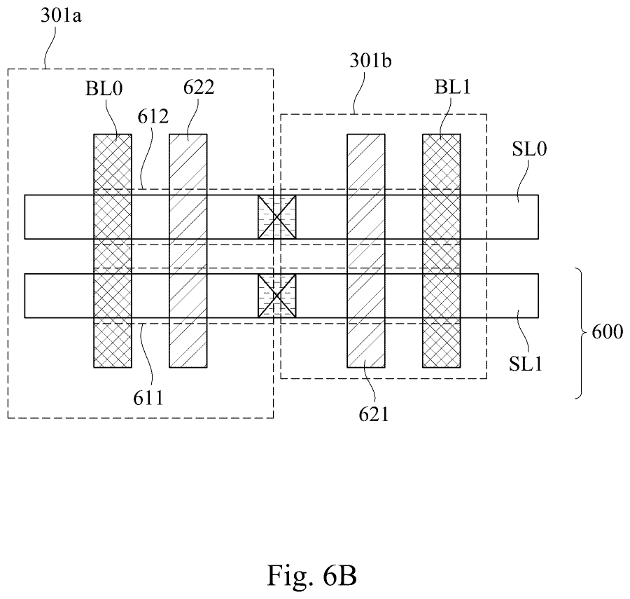

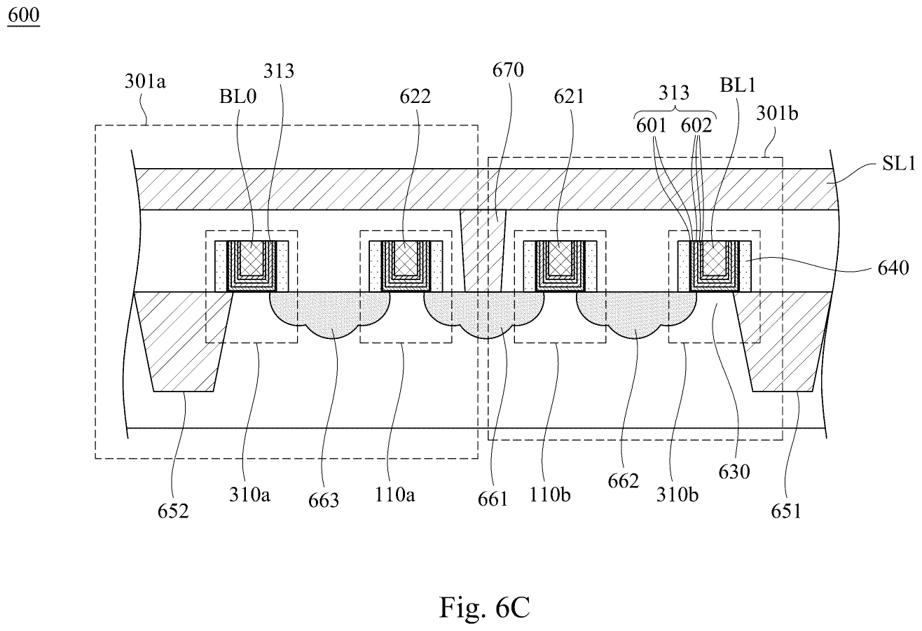

FIG. 6A is a circuit diagram of a memory unit 600 according to some embodiments of the present disclosure. As shown in FIG. 6A, the memory unit 600 includes resistive non-volatile memories 301a and 301b; their structures are essentially the same and are arranged symmetrically with each other. Each of the resistive non-volatile memories 301a and 301b of FIG. 6A is substantially the same as the resistive non-volatile memory 301 of FIG. 3A.

In FIG. 6A, the gate 313 of the gate-resistively-changeable field effect transistor 310b is electrically connected to the bit line BL1, the first terminal 311 of the gate-resistively-changeable field effect transistor 310b is floated, and the two terminals of the unipolar source/channel/drain diode 110b are electrically connected to the source line SL1 and the second terminal 312 of the gate-resistively-changeable field effect transistor 310b respectively. The gate 313 of the gate-resistively-changeable field effect transistor 310a is electrically connected to bit line BL0, the first terminal 311 of the gate-resistively-changeable field effect transistor 310a is floated, and the two terminals 111 and 112 of the unipolar source/channel/drain diode 110a are electrically connected to the source line SL1 and the second terminal 312 of the gate-resistively-changeable field effect transistor 310a.

FIG. 6B is a schematic layout diagram of a memory unit 600 according to some embodiments of the present disclosure. As shown in FIG. 6B, the source line SL0 is disposed above diffusion region 612, and the source line SL1 is disposed above diffusion region 611.

FIG. 6C is a cross-sectional view of a memory unit 600 according to some embodiments of the present disclosure. As shown in FIG. 6C, the unipolar source/channel/drain diode 110b includes a floating dummy gate 621, a first source/drain diffusion region 661 and a second source/drain diffusion region 662. The first source/drain diffusion region 661 and the second source/drain diffusion region 662 are respectively disposed at opposite sides of the floating dummy gate 621. The first source/drain diffusion region 661 contacts one terminal of the contact plug 670, and another terminal of the contact plug 670 contacts the source line SL1. In practice, for example, floating dummy gate 621 has no gate electrode and is not connected to any wire. The first source/drain diffusion region 661 and the second source/drain diffusion region 662 in FIG. 6C are respectively used as the two terminals 111 and 112 of the unipolar source/channel/drain diode 110b in FIG. 6A.

The unipolar source/channel/drain diodes 110a and 110b share the first source/drain diffusion region 661. The unipolar source/channel/drain diode 110a includes a floating dummy gate 622, a first source/drain diffusion region 661 and a third source/drain diffusion region 663. In practice, for example, the floating dummy gate 622 has no gate electrode and is not connected to any wire. The second source/drain diffusion region 661 and the third source/drain diffusion region 663 in FIG. 6C are respectively used as the two terminals 111 and 112 of the unipolar source/channel/drain diode 110a in FIG. 6A.

In FIG. 6C, the unipolar source/channel/drain diode 110b and the gate-resistively-changeable field effect transistor 310b share the second source/drain diffusion region 662. The gate-resistively-changeable field effect transistor 310b includes a shallow trench isolation 651. The shallow trench isolation 651 is in direct contact with the gate 313 of the gate-resistively-changeable field effect transistor 310b. The shallow trench isolation 651 and the second source/drain diffusion region 662 are respectively disposed at the opposite sides of the gate 313 of the gate-resistively-changeable field effect transistor 310b. the channel region 630 is disposed between the shallow trench isolation 651 and the second source/drain diffusion region 662. The shallow trench isolation 651 in FIG. 6C serves as the first terminal 311 of the gate-resistively-changeable field effect transistor 310b in FIG. 6A, and the second source/drain diffusion region 662 in FIG. 6C serves as the second terminal 312 of the gate-resistively-changeable field effect transistor 310b in FIG. 6A.

In practice, for example, the gate 313 of the gate-resistively-changeable field effect transistor 310b includes a gate dielectric layer 601 and a gate electrode layer 602. The outer side of the gate dielectric layer 601 is connected to the gate spacer 640, the inner side of the gate dielectric layer 601 is connected to the outer side of the gate electrode layer 602, and the inner side of the gate electrode layer 602 is connected to the bit line BL1.

The unipolar source/channel/drain diode 110a and the gate-resistively-changeable field effect transistor 310a share the third source/drain diffusion region 663. The gate-resistively-changeable field effect transistor 310a includes shallow trench isolation 652. The shallow trench isolation 652 is in direct contact with the gate 313 of the gate-resistively-changeable field effect transistor 310a. The shallow trench isolation 652 and the third source/drain diffusion region 663 are respectively disposed at the opposite sides of the gate 313 of the gate-resistively-changeable field effect transistor 310a. The channel region is disposed between the shallow trench isolation 652 and the third source/drain diffusion region 663. The shallow trench isolation 652 in FIG. 6C serves as the first terminal 311 of the gate-resistively-changeable field effect transistor 310a in FIG. 6A, and the third source/drain diffusion region 663 in FIG. 6C serves as the second terminal 312 of the gate-resistively-changeable field effect transistor 310a in FIG. 6A.

In other embodiments, the circuits of the resistive non-volatile memories 301-304 in FIGS. 3A-3D can be applied to the cross-sectional structure in FIG. 6C, and thus is not repeated herein.

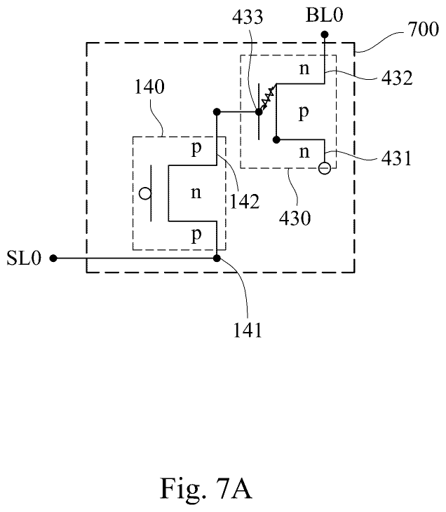

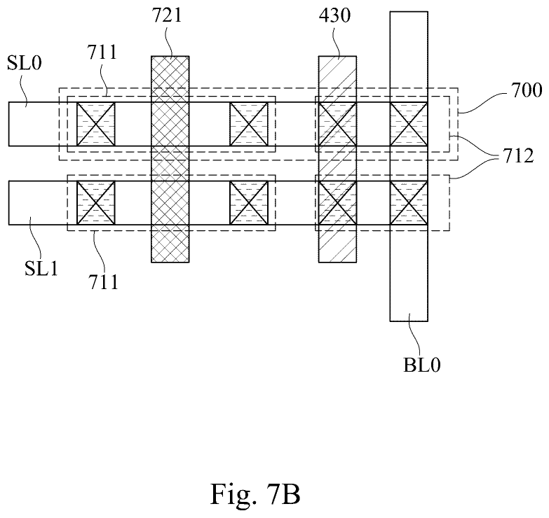

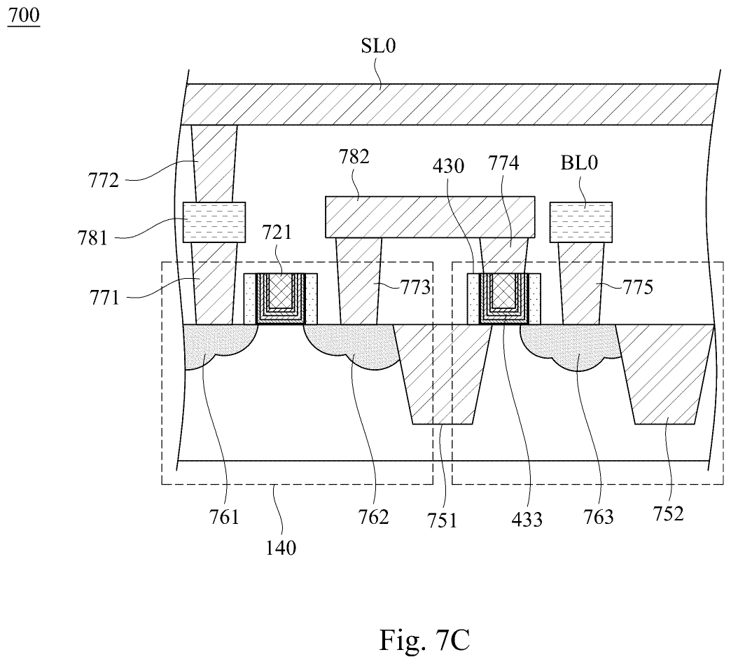

FIG. 7A is a circuit diagram of a resistive non-volatile memory 700 according to some embodiments of the present disclosure. The internal structure of the resistive non-volatile memory 700 of FIG. 7A is substantially the same as the internal structure of the resistive non-volatile memory 403 of FIG. 4C.

FIG. 7B is a schematic layout diagram of a resistive non-volatile memory 700 according to some embodiments of the present disclosure. FIG. 7B shows N-type well region 711 and P-type well region 712.

FIG. 7C is a cross-sectional view of a resistive non-volatile memory 700 according to some embodiments of the present disclosure. As shown in FIG. 7C, the unipolar source/channel/drain diode 140 includes a floating dummy gate 721, a first source/drain diffusion region 761 and a second source/drain diffusion region 762. The first source/drain diffusion region 761 and the second source/drain diffusion region 762 are respectively disposed at opposite sides of the floating dummy gate 721.

In FIG. 7C, the resistive non-volatile memory 700 further includes a first conductive layer 781, a second conductive layer 782, a first contact plug 771, a second contact plug 772, a third contact plug 773 and a fourth contact plug 774. The first conductive layer 781 and the second conductive layer 782 are electrically isolated from each other. The two terminals of the first contact plug 771 are in contact with the first source/drain diffusion region 761 and the first conductive layer 781 respectively. The two terminals of second contact plug 772 are in contact with first conductive layer 781 and source line SL0 respectively. The two terminals of the third contact plug 773 are in contact with the second source/drain diffusion region 762 and the second conductive layer 782 respectively. The two terminals of the fourth contact plug 774 are in contact with the gate 433 of the gate-resistively-changeable field effect transistor 430 and the second conductive layer 782 respectively.

In FIG. 7C, the gate-resistively-changeable field effect transistor 430 includes shallow trench isolation 751 and a third source/drain diffusion region 763. The shallow trench isolation 751 is in direct contact with the gate 433 of the gate-resistively-changeable field effect transistor 430. The shallow trench isolation 751 in FIG. 7C serves as the first terminal 431 of the gate-resistively-changeable field effect transistor 430 in FIG. 7A. The third source/drain diffusion region 763 and the shallow trench isolation 751 are respectively disposed at opposite sides of the gate 433 of the gate-resistively-changeable field effect transistor 430. The third source/drain diffusion region 763 in FIG. 7C serves as the second terminal 432 of the gate-resistively-changeable field effect transistor 430. The shallow trench isolation 752 is adjacent to the third source/drain diffusion region 763.

In FIG. 7C, the resistive non-volatile memory 700 further includes a fifth contact plug 775. The two terminals of fifth contact plug 775 are in contact with third source/drain diffusion region 763 and bit line BL0 respectively.

In other embodiments, the circuits of the resistive non-volatile memories 401-404 in FIGS. 4A-4D can be applied to the cross-sectional structure in FIG. 7C, and thus is not repeated herein.

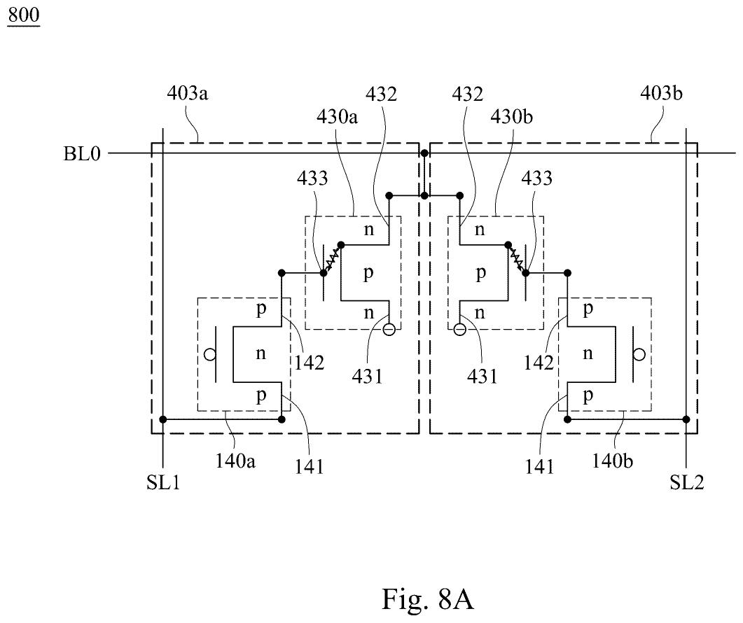

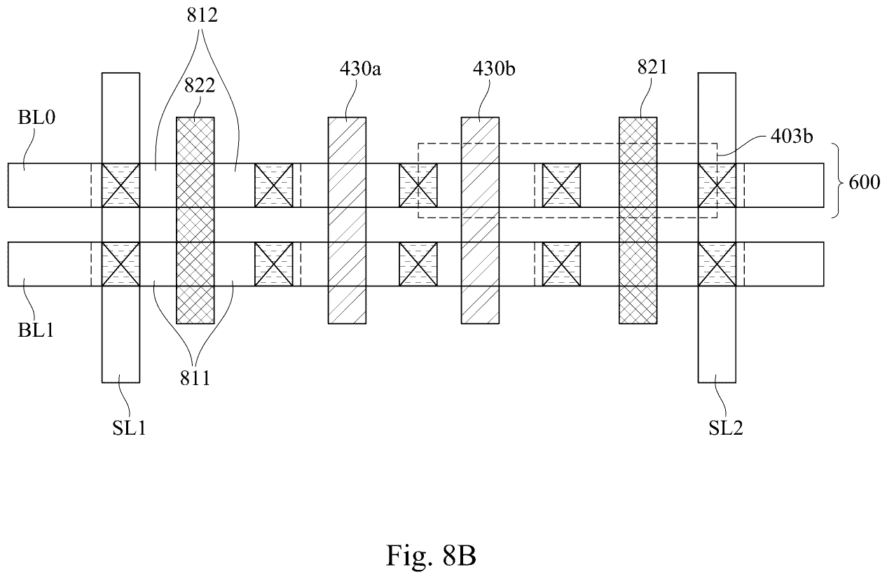

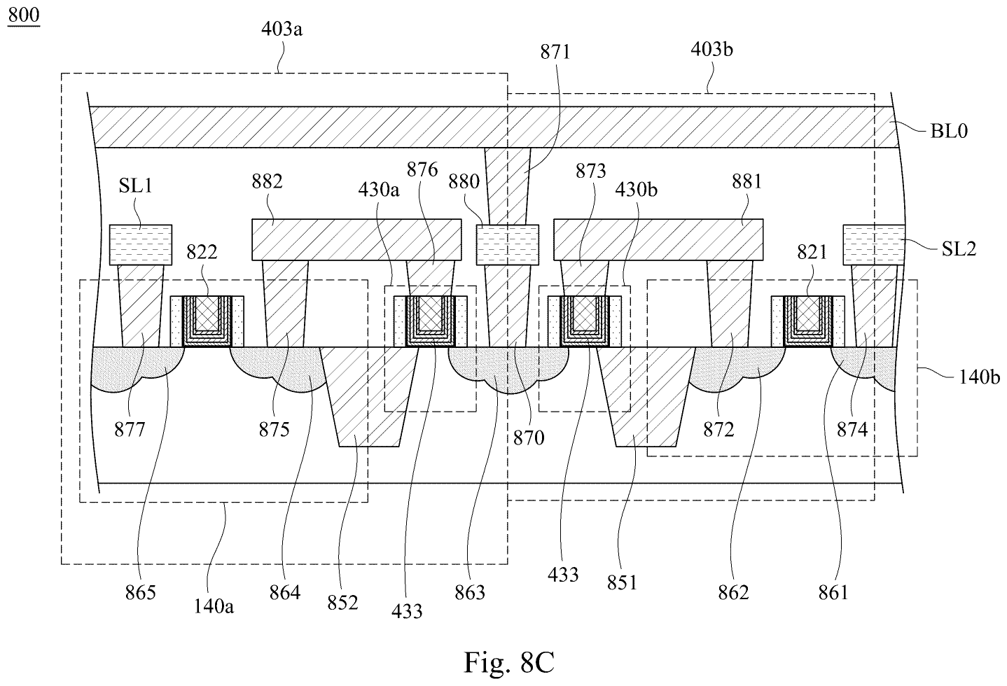

FIG. 8A is a circuit diagram of a memory unit 800 according to some embodiments of the present disclosure. The memory unit 800 includes resistive non-volatile memories 403a and 403b, which have substantially the same structure and are arranged symmetrically with each other. Each of the resistive non-volatile memory 403a, 403b of FIG. 8A is substantially the same as the resistive non-volatile memory 403 of FIG. 4C.

FIG. 8B is a schematic layout diagram of a memory unit 800 according to some embodiments of the present disclosure. As shown in FIG. 8B, the bit line BL0 is disposed above diffusion region 812, and the bit line BL1 is disposed above diffusion region 811.

FIG. 8C is a cross-sectional view of a memory unit 800 according to some embodiments of the present disclosure. As shown in FIG. 8C, the unipolar source/channel/drain diode 140a includes a floating dummy gate 822, a source/drain diffusion region 865 and a source/drain diffusion region 864. The source/drain diffusion region 865 and the source/drain diffusion region 864 are disposed at opposite sides of the floating dummy gate 822 respectively. The two terminals of contact plug 877 are in contact with the source/drain diffusion region 865 and source line SL1 respectively.

The gate-resistively-changeable field effect transistor 430a includes a gate 433, shallow trench isolation 852 and a source/drain diffusion region 863. The shallow trench isolation 852 and the source/drain diffusion region 863 are respectively disposed at opposite sides of the gate 433 of the gate-resistively-changeable field effect transistor 430a. The shallow trench isolation 852 is in direct contact with the gate 433 of the gate-resistively-changeable field effect transistor 430a. The shallow trench isolation 852 is adjacent to source/drain diffusion region 864. The two terminals of the contact plug 875 are in contact with the source/drain diffusion region 864 and the conductive layer 882 respectively, and the two terminals of the contact plug 876 are in contact with the gate 433 of the gate-resistively-changeable field effect transistor 430a and the conductive layer 882 respectively.

The two terminals of the contact plug 870 are in contact with the source/drain diffusion region 863 and the conductive layer 880 respectively. The two terminals of the contact plug 871 are in contact with the conductive layer 880 and the bit line BL0 respectively.

The unipolar source/channel/drain diode 140b includes a floating dummy gate 821, a source/drain diffusion region 861 and a source/drain diffusion region 862. The source/drain diffusion region 861 and the source/drain diffusion region 862 are respectively disposed at opposite sides of the floating dummy gate 821. The two terminals of contact plug 874 are in contact with the source/drain diffusion region 861 and the source line SL2 respectively. The two terminals of the contact plug 872 are in contact with the source/drain diffusion region 862 and the conductive layer 881 respectively.

The gate-resistively-changeable field effect transistor 430b includes a gate 433, shallow trench isolation 851 and a source/drain diffusion region 863. The shallow trench isolation 851 and the source/drain diffusion region 863 are respectively disposed at opposite sides of the gate 433 of the gate-resistively-changeable field effect transistor 430b. The shallow trench isolation 851 is in direct contact with the gate 433 of the gate-resistively-changeable field effect transistor 430b. The shallow trench isolation 851 is adjacent to source/drain diffusion region 862. The two terminals of the contact plug 873 are in contact with the gate 433 of the gate-resistively-changeable field effect transistor 430b and the conductive layer 881 respectively.

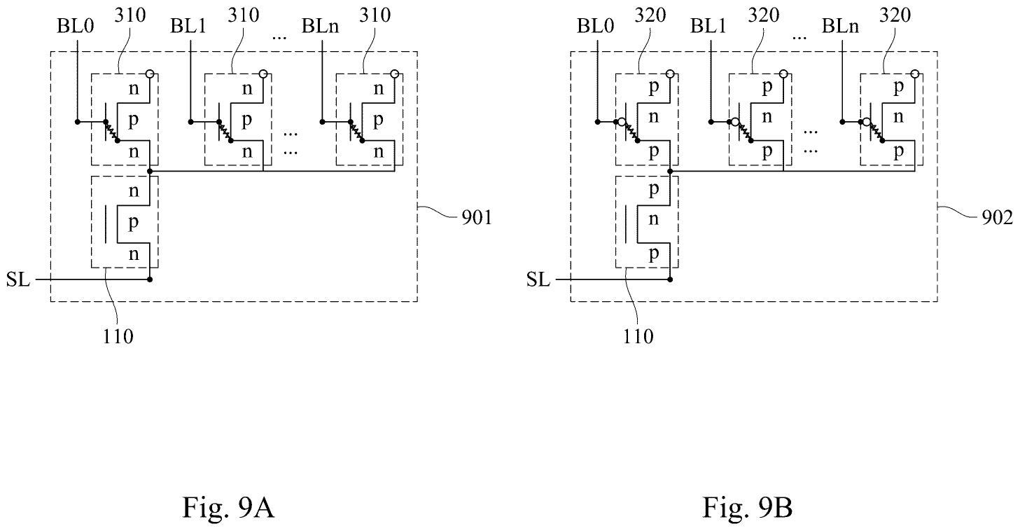

FIG. 9A is a circuit diagram of a resistive non-volatile memory 901 according to some embodiments of the present disclosure. The resistive non-volatile memory 901 in FIG. 9A is an extended architecture of the resistive non-volatile memory 301 in FIG. 3A. As shown in FIG. 9A, a plurality of gate-resistively-changeable field effect transistors 310 are electrically connected to bit lines BL0, BL1 . . . BLn respectively, and the two terminals of the unipolar source/channel/drain diode 110 are electrically connected to the source line SL and the gate-resistively-changeable field effect transistors 310.

FIG. 9B is a circuit diagram of a resistive non-volatile memory 902 according to some embodiments of the present disclosure. The resistive non-volatile memory 902 in FIG. 9B is an extended architecture of the resistive non-volatile memory 302 in FIG. 3B. As shown in FIG. 9B, a plurality of gate-resistively-changeable field effect transistors 320 are electrically connected to bit lines BL0, BL1 . . . BLn respectively, and the two terminals of unipolar source/channel/drain diode 110 are electrically connected to source line SL and the resistively-changeable field effect transistors 320.

In some embodiments of the present disclosure, the operating methods of resistive non-volatile memory 901-902 are all the same. In order to simplify the explanation, the following takes the operation of resistive non-volatile memory 901 as an example, the zero voltage is applied to one of the bit lines BL0, BL1 . . . BLn and the source line SL, and the nonzero voltage is applied to another of the bit lines BL0, BL1 . . . BLn and the source line SL, so as to operate the resistive non-volatile memory 901.

Specifically, in the forming process, when the gate-resistively-changeable field effect transistor 310 connected to the bit line BL0 in the resistive non-volatile memory 901 is selected, the forming voltage is applied to the bit line BL0, a voltage between one-half and one-fifth of the forming voltage is applied to the bit lines BL1 . . . BLn, and the zero voltage is applied to the source line SL, so that the gate dielectric layer of the gate of the gate-resistively-changeable field effect transistor 310 connected to the bit line BL0 can form a conductive filament; in the setting process, when the gate-resistively-changeable field effect transistor 310 connected to bit line BL0 in the resistive non-volatile memory 901 is selected, the setting voltage is applied to bit line BL0, a voltage between one-half and one-fifth of the setting voltage is applied to the bit lines BL1 . . . BLn, and the zero voltage is applied to the source line SL, so that the gate dielectric layer of the gate of the gate-resistively-changeable field effect transistor 310 connected to the bit line BL0 can be in the first resistance state, where the absolute value of the setting voltage is less than or equal to the absolute value of the forming voltage; in the resetting process, when the gate-resistively-changeable field effect transistor 310 connected to the bit line BL0 in the resistive non-volatile memory 901 is selected, a resetting voltage is applied to the bit line BL0, a voltage between one-half and one-fifth of the resetting voltage is applied to the bit lines BL1 . . . BLn, and the zero voltage is applied to the source line SL, so that the gate dielectric layer of the gate of the gate-resistively-changeable field effect transistor 310 connected to the bit line BL0 can be in the second resistance state, where the absolute value of the resetting voltage is less than the absolute value of the setting voltage; in the reading process, when the gate-resistively-changeable field effect transistor 310 connected to the bit line BL0 in the resistive non-volatile memory 901 is selected, a reading voltage is applied to the bit line BL0, a voltage between one-half and one-fifth of the reading voltage is applied to the bit lines BL1 . . . BLn, and the zero voltage is applied to the source line SL, where the absolute value of the reading voltage is less than the absolute value of resetting voltage. The reading circuit is based on the level of the read current to determine whether the resistive non-volatile memory 301 connected to the bit line BL0 has been set or reset.

On the other hand, in the forming process, when the resistive non-volatile memories 310 are not selected, a voltage between one-half and one-fifth of the forming voltage is applied to the source line SL, and the zero voltage is applied to the bit lines BL0, BL1 . . . BLn; in the setting process, when the resistive non-volatile memories 310 are not selected, a voltage between one-half and one-fifth of the setting voltage is applied to the source line SL, and the zero voltage is applied to the bit lines BL0, BL1 . . . BLn; in the resetting process, when the resistive non-volatile memories 310 are not selected, a voltage between one-half and one-fifth of the resetting voltage is applied to the source line SL, and the zero voltage is applied to the bit lines BL0, BL1 . . . BLn; in the reading process, when the resistive non-volatile memories 310 are not selected, a voltage between one-half and one-fifth of the reading voltage is applied to the source line SL, and the zero voltage is applied to the bit lines BL0, BL1 . . . BLn.

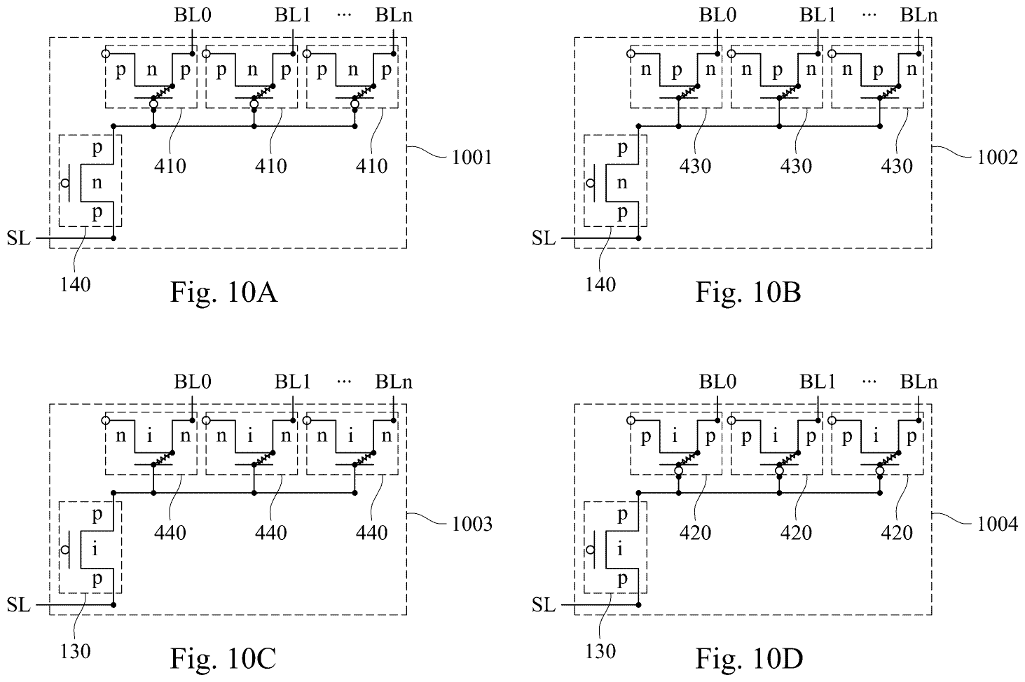

FIG. 10A is a circuit diagram of a resistive non-volatile memory 1001 according to some embodiments of the present disclosure. The resistive non-volatile memory 1001 in FIG. 10A is an extended architecture of the resistive non-volatile memory 401 in FIG. 4A. As shown in FIG. 10A, a plurality of gate-resistively-changeable field effect transistors 410 are electrically connected to bit lines BL0, BL1 . . . BLn respectively, and the two terminals of the unipolar source/channel/drain diode 140 are electrically connected to source line SL and the gate-resistively-changeable field effect transistors 410.

FIG. 10B is a circuit diagram of a resistive non-volatile memory according to some embodiments of the present disclosure. The resistive non-volatile memory 1002 in FIG. 10B is an extended architecture of the resistive non-volatile memory 403 in FIG. 4C. As shown in FIG. 10B, a plurality of gate-resistively-changeable field effect transistors 430 are electrically connected to bit lines BL0, BL1 . . . BLn respectively, and the two terminals of unipolar source/channel/drain diode 140 are electrically connected to source line SL and the gate-resistively-changeable field effect transistors 430.

FIG. 10C is a circuit diagram of a resistive non-volatile memory 1003 according to some embodiments of the present disclosure. As shown in FIG. 10C, a plurality of gate-resistively-changeable field effect transistors 440 are electrically connected to bit lines BL0, BL1 . . . BLn respectively, and the two terminals of unipolar source/channel/drain diode 130 are electrically connected to source line SL and the gate-resistively-changeable field effect transistors 440.

FIG. 10D is a circuit diagram of a resistive non-volatile memory 1004 according to some embodiments of the present disclosure. The resistive non-volatile memory 1004 in FIG. 10D is an extended architecture of the resistive non-volatile memory 402 in FIG. 4B. As shown in FIG. 10D, a plurality of gate-resistively-changeable field effect transistors 420 are electrically connected to bit lines BL0, BL1 . . . BLn respectively, and the two terminals of unipolar source/channel/drain diode 130 are electrically connected to source line SL and the resistively-changeable field effect transistors 420.

In some embodiments of the present disclosure, the operating methods of the resistive non-volatile memories 1001 to 1004 are all the same, and the voltage supply direction of the operating methods of resistive non-volatile memories 1001 to 1004 is opposite to the voltage supply direction of the operating methods of resistive non-volatile memories 901 to 902, so the details is not described again.

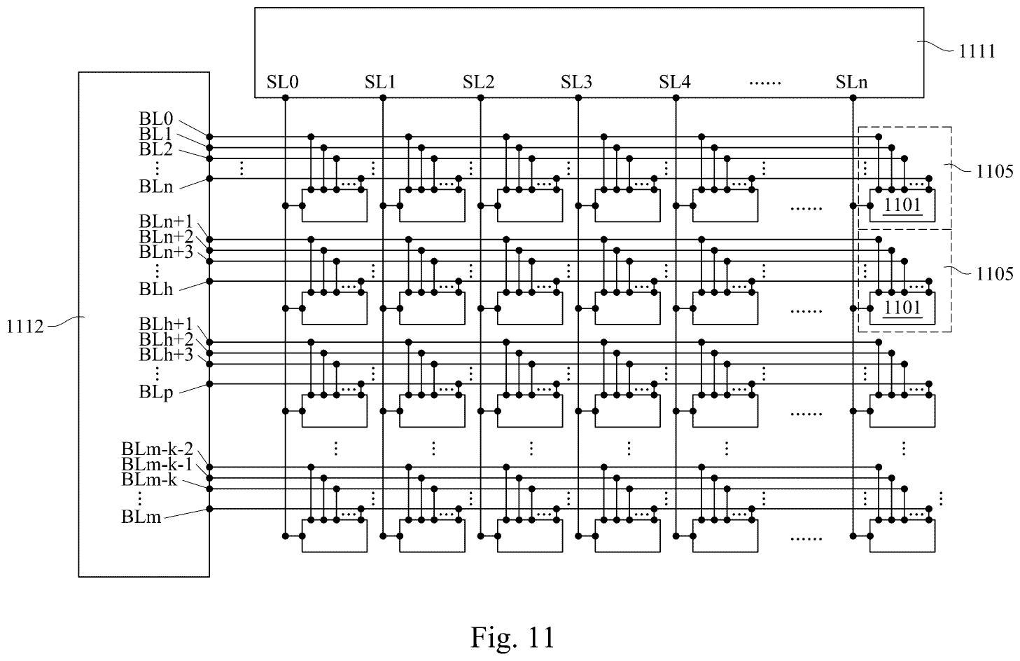

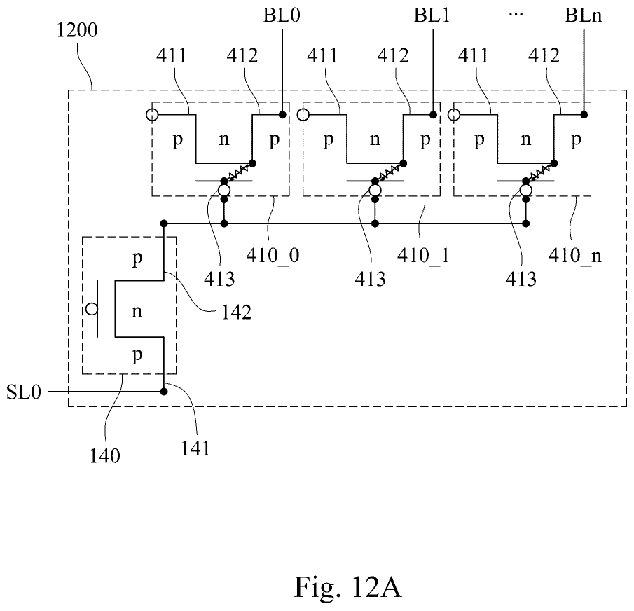

FIG. 11 is a circuit diagram of a memory circuit according to some embodiments of the present disclosure. As shown in FIG. 11, the memory circuit includes a plurality of memory units 1105 arranged in an array. Each memory unit 1105 includes a resistive non-volatile memory 1101. In practice, for example, the structure of the resistive non-volatile memory 1101 can be any one of the above-mentioned resistive non-volatile memories 901-902 and 1001-1004.

In FIG. 11, the circuit 1111 is electrically connected to a terminal of the corresponding unipolar source/channel/drain diode of the corresponding resistive non-volatile memory 1101 through a corresponding one of the source lines SL0-SLn. On the other hand, the circuit 1112 is electrically connected to a gate-resistively-changeable field effect transistor of the corresponding resistive non-volatile memory 1101 through the corresponding one of the bit lines BL0-BLn, BLn+1-BLh, BLh+1-BLp, BLm−k−2-BLm respectively. In practice, for example, the circuit 1111 includes a source line peripheral circuit and a control circuit, the circuit 1112 includes a bit line peripheral circuit and a control circuit, and the read circuit can be selectively set to the circuit 1111 or the circuit 1112.

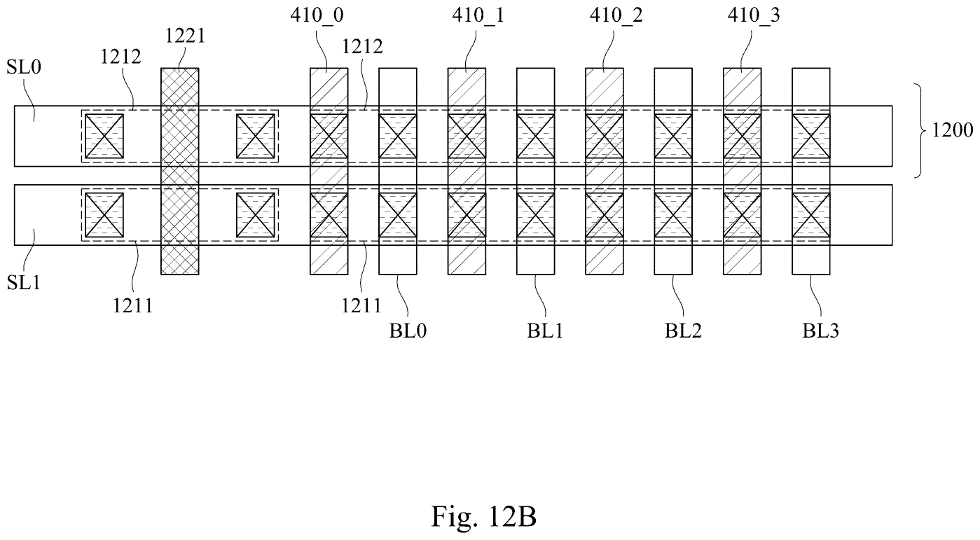

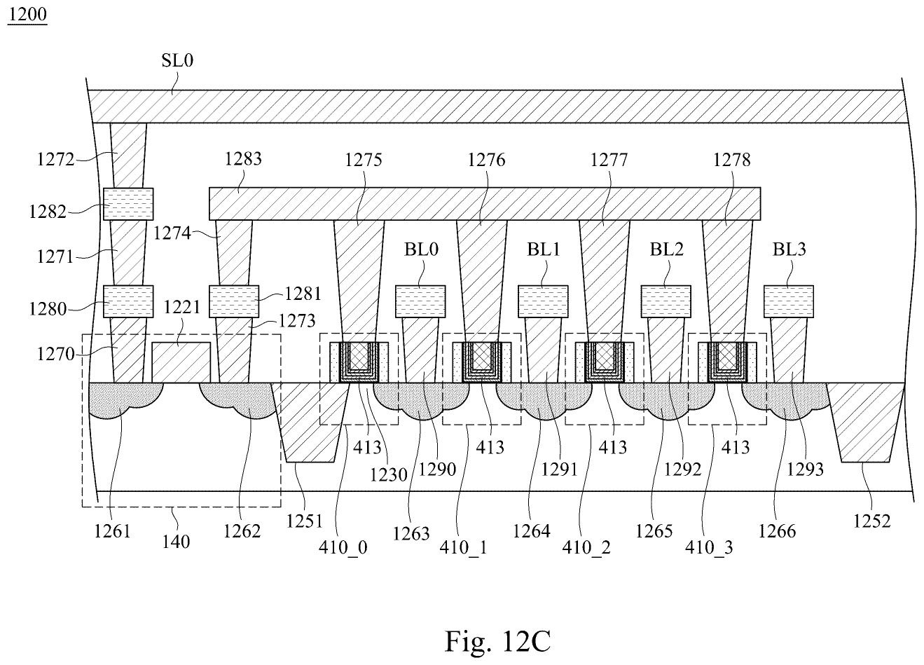

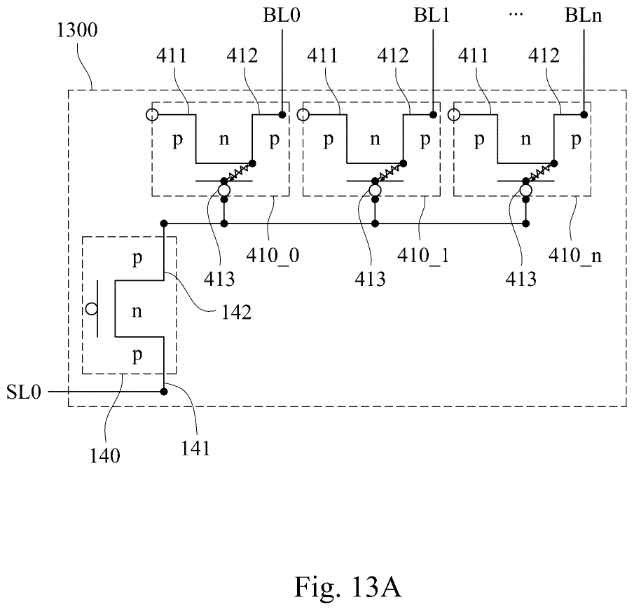

FIG. 12A is a circuit diagram of a resistive non-volatile memory 1200 according to some embodiments of the present disclosure. The internal structure of the resistive non-volatile memory 1200 of FIG. 12A is substantially the same as the internal structure of the resistive non-volatile memory 1001 of FIG. 10A. The structure of each of the gate-resistively-changeable field effect transistors 410_0-410_n is substantially the same as the structure of the gate-resistively-changeable field effect transistor 410.

FIG. 12B is a schematic layout diagram of a resistive non-volatile memory 1200 according to some embodiments of the present disclosure. As shown in FIG. 12B, the source line SL0 is disposed above the active region 1212, and the source line SL1 is disposed above the active region 1211.

FIG. 12C is a cross-sectional view of a resistive non-volatile memory 1200 according to some embodiments of the present disclosure. As shown in FIG. 12C, the unipolar source/channel/drain diode 140 includes a floating dummy gate 1221, a source/drain diffusion region 1261 and a source/drain diffusion region 1262. The source/drain diffusion region 1261 and the source/drain diffusion region 1262 are respectively disposed at opposite sides of the floating dummy gate 1221. The two terminals of the contact plug 1270 are in contact with the source/drain diffusion region 1261 and the conductive layer 1280 respectively. The two terminals of the contact plug 1271 are in contact with the conductive layer 1280 and the conductive layer 1282 respectively. The two terminals of the contact plug 1272 are in contact with the conductive layer 1282 and the source line SL0 respectively. The two terminals of the contact plug 1273 are in contact with the source/drain diffusion region 1262 and the conductive layer 1281 respectively. The two terminals of the contact plug 1274 are in contact with conductive layer 1281 and conductive layer 1283 respectively.

The gate-resistively-changeable field effect transistor 410_0 includes a gate 413, shallow trench isolation 1251 and a source/drain diffusion region 1263. The shallow trench isolation 1251 and the source/drain diffusion region 1263 are respectively disposed at opposite sides of the gate 413 of the gate-resistively-changeable field effect transistor 410_0. The shallow trench isolation 1251 is in direct contact with the gate 413 of the gate-resistively-changeable field effect transistor 410_0. The shallow trench isolation 1251 is adjacent to the source/drain diffusion region 1262. The two terminals of contact plug 1275 are in contact with the gate 413 and the conductive layer 1283 of the gate-resistively-changeable field effect transistor 410_0 respectively, and the two terminals of the contact plug 1290 are in contact with the source/drain diffusion region 1263 and the bit line BL0 respectively.

The gate-resistively-changeable field effect transistor 410_1 includes a gate 413, a source/drain diffusion region 1263 and a source/drain diffusion region 1264. The source/drain diffusion region 1263 and the source/drain diffusion region 1264 are respectively disposed at opposite sides of the gate 413 of the gate-resistively-changeable field effect transistor 410_1. The two terminals of contact plug 1276 are in contact with the gate 413 and the conductive layer 1283 of the gate-resistively-changeable field effect transistor 410_1 respectively, and the two terminals of the contact plug 1291 are in contact with the source/drain diffusion region 1264 and the bit line BL1 respectively.

The gate-resistively-changeable field effect transistor 410_2 includes a gate 413, a source/drain diffusion region 1264, and a source/drain diffusion region 1265. The source/drain diffusion region 1264 and the source/drain diffusion region 1265 are respectively disposed at opposite sides of the gate 413 of the gate-resistively-changeable field effect transistor 410_2. The two terminals of contact plug 1277 are in contact with the gate 413 and the conductive layer 1283 of gate-resistively-changeable field effect transistor 410_2 respectively, and the two terminals of contact plug 1292 are in contact with the source/drain diffusion region 1265 and the bit line BL2 respectively.

The gate-resistively-changeable field effect transistor 410_3 includes a gate 413, a source/drain diffusion region 1265 and a source/drain diffusion region 1266. The source/drain diffusion region 1265 and the source/drain diffusion region 1266 are respectively disposed at opposite sides of the gate 413 of the gate-resistively-changeable field effect transistor 410_3. The two terminals of the contact plug 1278 are in contact with the gate 413 and the conductive layer 1283 of the gate-resistively-changeable field effect transistor 410_3 respectively, and the two terminals of the contact plug 1293 are in contact with the source/drain diffusion region 1266 and the bit line BL3 respectively. The shallow trench isolation 1252 is adjacent to the source/drain diffusion region 1266.

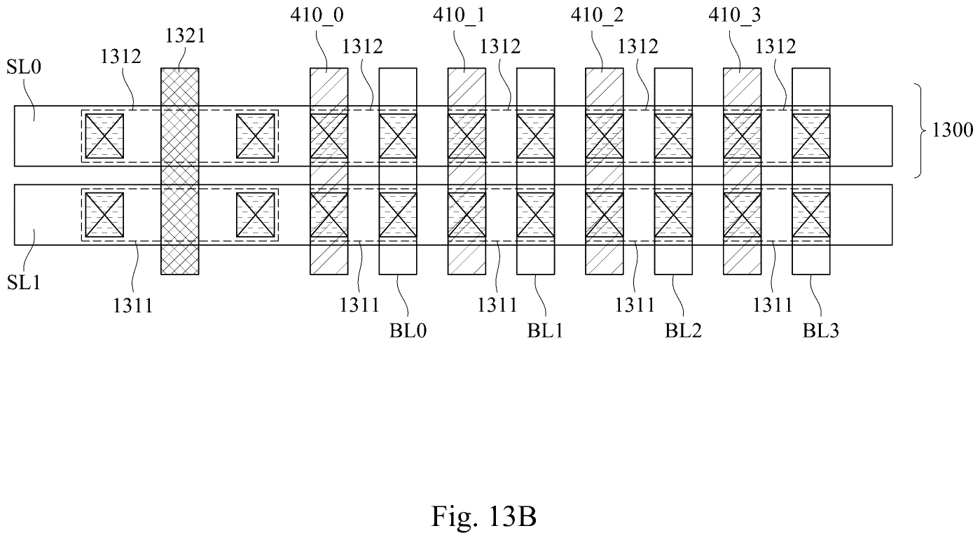

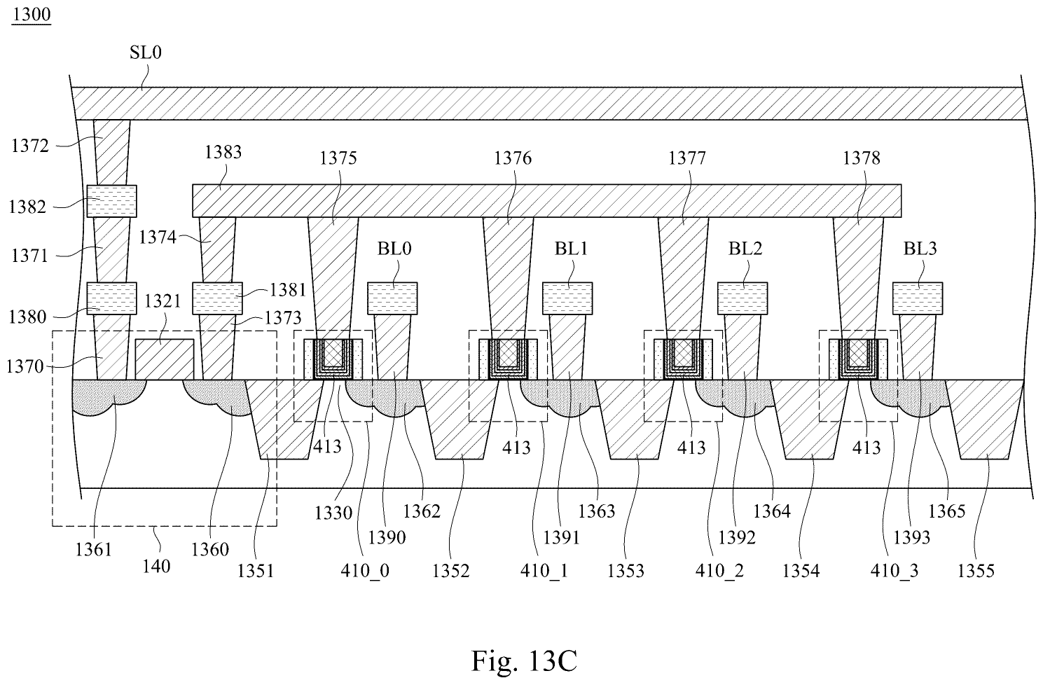

FIG. 13A is a circuit diagram of a resistive non-volatile memory 1300 according to some embodiments of the present disclosure. The internal structure of the resistive non-volatile memory 1300 of FIG. 13A is substantially the same as the internal structure of the resistive non-volatile memory 1001 of FIG. 10A.

FIG. 13B is a schematic layout diagram of a resistive non-volatile memory 1300 according to some embodiments of the present disclosure. As shown in FIG. 13B, the source line SL0 is disposed above the active region 1312, and the source line SL1 is disposed above the active region 1311.

FIG. 13C is a cross-sectional view of a resistive non-volatile memory 1300 according to some embodiments of the present disclosure. As shown in FIG. 13C, the unipolar source/channel/drain diode 140 includes a floating dummy gate 1321, a source/drain diffusion region 1361 and a source/drain diffusion region 1360. The source/drain diffusion region 1361 and the source/drain diffusion region 1360 are respectively disposed at opposite sides of the floating dummy gate 1321. The two terminals of contact plug 1370 are in contact with source/drain diffusion region 1361 and conductive layer 1380 respectively. The two terminals of contact plug 1371 are in contact with conductive layer 1380 and conductive layer 1382 respectively. The two terminals of contact plug 1372 are in contact with conductive layer 1382 and source line SL0 respectively. The two terminals of the contact plug 1373 are in contact with the source/drain diffusion region 1360 and the conductive layer 1381 respectively. The two terminals of the contact plug 1374 are in contact with the conductive layer 1381 and the conductive layer 1383 respectively.

The gate-resistively-changeable field effect transistor 410_0 includes a gate 413, shallow trench isolation 1351 and a source/drain diffusion region 1362. The shallow trench isolation 1351 and the source/drain diffusion region 1362 are respectively disposed at opposite sides of gate 413 of gate-resistively-changeable field effect transistor 410_0. The channel region 1330 is disposed between the shallow trench isolation 1351 and the source/drain diffusion region 1362. The shallow trench isolation 1351 is in direct contact with the gate 413 of the gate-resistively-changeable field effect transistor 410_0. The shallow trench isolation 1351 is adjacent to the source/drain diffusion region 1360. The two terminals of the contact plug 1375 are in contact with the gate 413 and the conductive layer 1383 of gate-resistively-changeable field effect transistor 410_0 respectively, and the two terminals of contact plug 1390 are in contact with the source/drain diffusion region 1362 and the bit line BL0 respectively.

The gate-resistively-changeable field effect transistor 410_1 includes a gate 413, shallow trench isolation 1352 and a source/drain diffusion region 1363. The shallow trench isolation 1352 and the source/drain diffusion region 1363 are respectively disposed at opposite sides of the gate 413 of the gate-resistively-changeable field effect transistor 410_1. The shallow trench isolation 1352 is in direct contact with the gate 413 of the gate-resistively-changeable field effect transistor 410_1. The shallow trench isolation 1352 is adjacent to the source/drain diffusion region 1362. The two terminals of the contact plug 1376 are in contact with the gate 413 and the conductive layer 1383 of gate-resistively-changeable field effect transistor 410_1 respectively, and the two terminals of the contact plug 1391 are in contact with the source/drain diffusion region 1363 and the bit line BL1 respectively.

The gate-resistively-changeable field effect transistor 410_2 includes a gate 413, shallow trench isolation 1353 and a source/drain diffusion region 1364. The shallow trench isolation 1353 and the source/drain diffusion region 1364 are respectively disposed at opposite sides of the gate 413 of the gate-resistively-changeable field effect transistor 410_2. The shallow trench isolation 1353 is in direct contact with the gate 413 of the gate-resistively-changeable field effect transistor 410_2. The shallow trench isolation 1353 is adjacent to the source/drain diffusion region 1363. The two terminals of the contact plug 1377 are respectively in contact with the gate 413 and the conductive layer 1383 of the gate-resistively-changeable field effect transistor 410_2, and the two terminals of the contact plug 1392 are in contact with the source/drain diffusion region 1364 and the bit line BL2 respectively.

The gate-resistively-changeable field effect transistor 410_3 includes a gate 413, shallow trench isolation 1354 and a source/drain diffusion region 1365. The shallow trench isolation 1354 and the source/drain diffusion region 1365 are respectively disposed at opposite sides of the gate 413 of the gate-resistively-changeable field effect transistor 410_3. The shallow trench isolation 1354 is in direct contact with the gate 413 of the gate-resistively-changeable field effect transistor 410_3. The shallow trench isolation 1354 is adjacent to the source/drain diffusion region 1364. The two terminals of the contact plug 1378 are in contact with the gate 413 and the conductive layer 1383 of the gate-resistively-changeable field effect transistor 410_3 respectively, and the two terminals of the contact plug 1393 are in contact with source/drain diffusion region 1365 and bit line BL3 respectively.

In view of the above, technical advantages are generally achieved, by embodiments of the present disclosure. The resistive non-volatile memory of the present disclosure does not require additional word lines and related circuits, achieving the ultra-scaled chip size in favor of CMOS continual scaling and simpler configuration arrangement of the chip with higher cost efficiency.

It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

What is claimed is:

1. A resistive non-volatile memory, comprising:
at least one gate-resistively-changeable field effect transistor electrically connected to at least one bit line; and
a unipolar source/channel/drain diode implemented by a field effect transistor without a gate electrode, and two terminals of the unipolar source/channel/drain diode being electrically connected to a source line and the at least one gate-resistively-changeable field effect transistor respectively.

2. The resistive non-volatile memory of claim 1, wherein a gate of the at least one gate-resistively-changeable field effect transistor is electrically connected to the at least one bit line, and a first terminal of the at least one gate-resistively-changeable field effect transistor is floated, two terminals of the unipolar source/channel/drain diode are electrically connected to the source line and a second terminal of the at least one gate-resistively-changeable field effect transistor, and the unipolar source/channel/drain diode is a npn diode or a nin diode.

3. The resistive non-volatile memory of claim 2, wherein the unipolar source/channel/drain diode comprises:
a floating dummy gate; and
a first source/drain diffusion region and a second source/drain diffusion region disposed at opposite sides of the floating dummy gate, wherein the first source/drain diffusion region contacts a terminal of a contact plug, and another terminal of the contact plug contacts the source line.

4. The resistive non-volatile memory of claim 3, wherein the unipolar source/channel/drain diode and the at least one gate-resistively-changeable field effect transistor share the second source/drain diffusion region, and the at least one gate-resistively-changeable field effect transistor comprises:
a shallow trench isolation in direct contact with the gate of the at least one gate-resistively-changeable field effect transistor, wherein the shallow trench isolation and the second source/drain diffusion region are respectively disposed at opposite sides of the gate of the at least one gate-resistively-changeable field effect transistor, the shallow trench isolation serves as the first terminal of the at least one gate-resistively-changeable field effect transistor, and the second source/drain diffusion region serves as the second terminal of the at least one gate-resistively-changeable field effect transistor.

5. The resistive non-volatile memory of claim 1, wherein two terminals of the unipolar source/channel/drain diode are electrically connected to the source line and a gate of the at least one gate-resistively-changeable field effect transistor respectively, a first terminal of the at least one gate-resistively-changeable field effect transistor is floated, a second terminal of the at least one gate-resistively-changeable field effect transistor is electrically connected to the at least one bit line, and the unipolar source/channel/drain diode is a pnp diode or a pip diode.

6. The resistive non-volatile memory of claim 5, wherein the unipolar source/channel/drain diode comprises:
a floating dummy gate; and
a first source/drain diffusion region and a second source/drain diffusion region disposed at opposite sides of the floating dummy gate.

7. The resistive non-volatile memory of claim 6, further comprising:
a first conductive layer and a second conductive layer electrically isolated from each other;
a first contact plug having two terminals in contact with the first source/drain diffusion region and the first conductive layer respectively;
a second contact plug having two terminals in contact with the first conductive layer and the source line respectively;
a third contact plug having two terminals in contact with the second source/drain diffusion region and the second conductive layer respectively; and
a fourth contact plug having two terminals in contact with the gate of the at least one gate-resistively-changeable field effect transistor and the second conductive layer respectively.

8. The resistive non-volatile memory of claim 7, wherein the at least one gate-resistively-changeable field effect transistor comprises:
a shallow trench isolation in direct contact with the gate of the at least one gate-resistively-changeable field effect transistor, and the shallow trench isolation serving as the first terminal of the at least one gate-resistively-changeable field effect transistor; and
a third source/drain diffusion region and the shallow trench isolation disposed at opposite sides of the gate of the at least one gate-resistively-changeable field effect transistor, and the third source/drain diffusion region serving as the second terminal of the at least one gate-resistively-changeable field effect transistor.

9. The resistive non-volatile memory of claim 8, further comprising:
a fifth contact plug having two terminals contact the third source/drain diffusion region and the at least one bit line respectively.

10. A memory circuit, comprising:
a plurality of memory units arranged in an array, each of the memory units comprising a resistive non-volatile memory, and the resistive non-volatile memory comprising:
at least one gate-resistively-changeable field effect transistor electrically connected to at least one bit line; and
a unipolar source/channel/drain diode implemented by a field effect transistor without a gate electrode, two terminals of the unipolar source/channel/drain diode respectively electrically connected to a source line and the at least one gate-resistively-changeable field effect transistor.

11. The memory circuit of claim 10, wherein each of the memory units comprises another resistive non-volatile memory, and a terminal of the another resistive non-volatile memory is electrically connected to the resistive non-volatile memory and the at least one bit line, and another terminal of the another resistive non-volatile memory is electrically connected to another source line.

12. The memory circuit of claim 10, wherein each of the memory units comprises another resistive non-volatile memory, and a terminal of the another resistive non-volatile memory is electrically connected to the resistive non-volatile memory and the source line, and another terminal of the another resistive non-volatile memory is electrically connected to the at least one bit line.

13. The memory circuit of claim 10, wherein a gate of the at least one gate-resistively-changeable field effect transistor is electrically connected to the at least one bit line, a first terminal of the at least one gate-resistively-changeable field effect transistor is floated, two terminals of the unipolar source/channel/drain diode are electrically connected to the source line and a second terminal of the at least one gate-resistively-changeable field effect transistor, each of the memory units comprises another resistive non-volatile memory, and the another resistive non-volatile memory comprises:
at least another gate-resistively-changeable field effect transistor having a gate electrically connected to at least another bit line, and a first terminal of the at least another gate-resistively-changeable field effect transistor being floated; and
another unipolar source/channel/drain diode implemented by another field effect transistor without a gate electrode, two terminals of the another unipolar source/channel/drain diode being respectively electrically connected to the source line and a second terminal of the at least another gate-resistively-changeable field effect transistor.

14. The memory circuit of claim 10, wherein two terminals of the unipolar source/channel/drain diode are electrically connected to the source line and a gate of the at least one gate-resistively-changeable field effect transistor, a first terminal of the at least one gate-resistively-changeable field effect transistor is floated, a second terminal of the at least one gate-resistively-changeable field effect transistor is electrically connected to the at least one bit line, each of the memory units comprises another resistive non-volatile memory, and the another resistive non-volatile memory comprises:
at least another gate-resistively-changeable field effect transistor having a first terminal being floated, and a second terminal of the at least another gate-resistively-changeable field effect transistor being electrically connected to the at least one bit line; and
another unipolar source/channel/drain diode implemented by another field effect transistor without a gate electrode, two terminals of the another unipolar source/channel/drain diode being electrically connected to another source line and a gate of the at least another gate-resistively-changeable field effect transistor.

15. An operation method of a resistive non-volatile memory, the resistive non-volatile memory comprising a gate-resistively-changeable field effect transistor and a unipolar source/channel/drain diode connected to each other, and the operation method comprising steps of:
applying a zero voltage to one of a bit line and a source line, and applying a nonzero voltage to another of the bit line and the source line to operate the resistive non-volatile memory, wherein the gate-resistively-changeable field effect transistor is electrically connected to the bit line, the unipolar source/channel/drain diode is implemented by a field effect transistor without a gate electrode, two terminals of the unipolar source/channel/drain diode are electrically connected to the source line and the gate-resistively-changeable field effect transistor respectively.

16. The operation method of claim 15, wherein a gate of the gate-resistively-changeable field effect transistor is electrically connected to the bit line, a first terminal of the gate-resistively-changeable field effect transistor is floated, two terminals of the unipolar source/channel/drain diode are electrically connected to the source line and a second terminal of the gate-resistively-changeable field effect transistor, the unipolar source/channel/drain diode is a npn diode or a nin diode, and the operation methods comprises:
in a forming process, when the resistive non-volatile memory is selected, applying a forming voltage to the bit line, and applying the zero voltage to the source line;
in a setting process, when the resistive non-volatile memory is selected, applying a setting voltage to the bit line, and applying the zero voltage to the source line, wherein an absolute value of the setting voltage is less than or equal to an absolute value of the forming voltage;
in a resetting process, when the resistive non-volatile memory is selected, applying a resetting voltage to the bit line, and applying the zero voltage to the source line, wherein an absolute value of the resetting voltage is less than the absolute value of the setting voltage; and
in a reading process, when the resistive non-volatile memory is selected, applying a reading voltage to the bit line, and applying the zero voltage to the source line, where an absolute value of the reading voltage is less than the absolute value of the resetting voltage.

17. The operation method of claim 16, further comprising:
in the forming process, when the resistive non-volatile memory is not selected, applying a voltage between one-half and one-fifth of the forming voltage to the source line, and applying the zero voltage is applied to the bit line;
in the setting process, when the resistive non-volatile memory is not selected, applying a voltage between one-half and one-fifth of the setting voltage to the source line, and applying the zero voltage to the bit line;
in the resetting process, when the resistive non-volatile memory is not selected, applying a voltage between one-half and one-fifth of the resetting voltage to the source line, and applying the zero voltage to the bit line; and
in the reading process, when the resistive non-volatile memory is not selected, applying a voltage between one-half and one-fifth of the reading voltage to the source line, and applying the zero voltage to the bit line.

18. The operation method of claim 15, wherein two terminals of the unipolar source/channel/drain diode are electrically connected to the source line and a gate of the gate-resistively-changeable field effect transistor, a first terminal of the gate-resistively-changeable field effect transistor is floated, a second terminal of the gate-resistively-changeable field effect transistor is electrically connected to the bit line, the unipolar source/channel/drain diode is a pnp diode or a pip diode, and the operation methods comprises:
in a forming process, when the resistive non-volatile memory is selected, applying a forming voltage to the source line, and applying the zero voltage to the bit line;
in a setting process, when the resistive non-volatile memory is selected, applying a setting voltage to the source line, and applying the zero voltage to the bit line, wherein an absolute value of the setting voltage is less than or equal to an absolute value of the forming voltage;
in a resetting process, when the resistive non-volatile memory is selected, applying a resetting voltage to the source line, and applying the zero voltage to the bit line, wherein an absolute value of the resetting voltage is less than the absolute value of the setting voltage; and
in a reading process, when the resistive non-volatile memory is selected, applying a reading voltage to the source line, and applying the zero voltage to the bit line, wherein an absolute value of the reading voltage is less than the absolute value of the resetting voltage.

19. The operation method of claim 18, further comprising:
in the forming process, when the resistive non-volatile memory is not selected, applying a voltage between one-half and one-fifth of the forming voltage to the bit line, and applying the zero voltage to the source line;
in the setting process, when the resistive non-volatile memory is not selected, applying a voltage between one-half and one-fifth of the setting voltage to the bit line, and applying the zero voltage to the source line;
in the resetting process, when the resistive non-volatile memory is not selected, applying a voltage between one-half and one-fifth of the resetting voltage to the bit line, and applying the zero voltage to the source line; and
in the reading process, when the resistive non-volatile memory is not selected, applying a voltage between one-half and one-fifth of the reading voltage to the bit line, and applying the zero voltage to the source line.
